(19) United States
(12) Patent Application Publication
(10) Pub. No.: US 2003/0146458 A1
(43) Pub. Date: Aug. 7, 2003

(54) Semiconductor device and process for forming same

(75) Inventors: Masatada Horiuchi, Koganei (JP); Takashi Takahama, Higashimurayama (JP)

Correspondence Address: Stanley P. Fisher, Reed Smith LLP, Suite 1400, 3110 Fairview Park Drive, Falls Church, VA, 22042-4503, US

(73) Assignee: Hitachi, Ltd.

(21) Appl. No.: 10/315,141

(22) Filed: Dec. 10, 2002

(30) Foreign Application Priority Data
Feb. 4, 2002 (JP) 2002-026580

(51) Int. Cl. H01L 29/76

(52) U.S. Cl. 257/288

(57) ABSTRACT

Disclosed is a method of manufacturing a semiconductor device capable of improving the reliability of the semiconductor device, which has a field effect transistor having a source-drain structure with a shallow junction. In the process for realizing the reduction of the resistance in a diffusion layer for a source and drain with a shallow junction, in which a part of an amorphous layer formed by the ion implantation for forming a diffusion layer for a source and drain is selectively melted and recrystallized by the use of laser irradiation, in order to prevent the occurrence of defects such as short circuit at a portion where a region to be melted and a gate electrode are overlapped with each other, ion implantation is performed after the formation of a first gate sidewall insulator on a sidewall of the gate electrode so as to obtain a structure in which the amorphous layer is not overlapped with the gate electrode. In this manner, it is possible to melt and recrystallize the amorphous layer without causing the defects such as short circuit.

### TECHNICAL FIELD OF THE INVENTION

The present invention relates to a method of manufacturing a semiconductor device and a semiconductor device technology. More specifically, the present invention relates to a technique effectively applied to a method of manufacturing a semiconductor device having a field effect transistor and to such a semiconductor device.

### BACKGROUND OF THE INVENTION

The miniaturization of an insulated gate field effect transistor that constitutes an ultra large scale integration circuit device, more particularly, a MOS (Metal Oxide semiconductor) field effect transistor (hereinafter, simply abbreviated as MOS) has been progressed based on the scaling law. For example, a hyperfine MOS having a gate length of 50 nm or shorter has been disclosed. With the advancement of the miniaturization of the gate electrode length and the reduction of the power supply voltage, ultra-shallow junction of the source diffusion layer and the drain diffusion layer has been proceeded in the hyperfine MOS in order to reduce the punch-through current. The ion implantation method is usually used for the introduction of impurities in the hyperfine MOS, and the high-temperature short-time annealing is used for the activation of the implanted ions so as to minimize the redistribution of the impurities and to obtain a more abrupt impurity profile. However, the above-described techniques have been reaching their limits. In the P+N junction, for example, the sheet resistance is 520 Ω/□ when the junction depth is 40 nm. However, when the junction depth is reduced 25%, to 30 nm, the sheet resistance is rapidly increased about 2.5 times, to 1300 Ω/□. This is a result of the case in which the ion implantation of boron difluoride (BF₂) is performed under the conditions that the acceleration energy is 3 keV and the dose amount is 1×10¹⁵/cm², and the temperature of the high-temperature short-time annealing is reduced from 1050 to 1000° C. However, even if the dose amount is increased while keeping the conditions of the annealing unchanged, the mere increase of the junction depth is caused and effect for reducing the resistance can be hardly expected. This is because the ions already implanted by the ion implantation with low acceleration energy are emitted due to the sputtering phenomenon by the ion implantation, and only about the half of the implanted amount remains in the substrate. Furthermore, even if the acceleration energy in the ion implantation is reduced to, for example, 2 keV, the effect for reducing the junction depth is extremely small. This is because a low concentration region reaches a deeper position in comparison to an implantation range due to the channeling phenomenon and the acceleration energy distribution at the time of the ion implantation. Alternatively, this is because the abnormal diffusion of the low concentration region due to the enhanced diffusion phenomenon in a relatively low temperature annealing at about 800° C. termed as TED (transient enhanced diffusion) is inevitable. The heating process and the cooling process in the short-time high-temperature annealing are several tens to several hundreds ° C./sec in the current apparatus performance, and such a temperature change is too rapid to ignore in the low temperature annealing.

As a technique for eliminating the barrier to realize the ultra-shallow, low-resistive junction based on the short-time high-temperature annealing, a technique is known in which a laser is irradiated to an ion implanted region to reduce the resistance of the irradiated region. This technique is disclosed in, for example, Japanese Patent Laid-Open No. 3-163822. In this disclosure, a technique is described in which, after forming an impurity-implanted region for forming a highly concentrated diffusion layer for a source and drain of a MOS, a low temperature annealing at about 600° C. is performed to recrystallize an amorphous region in the impurity-implanted region, and then, a laser is irradiated to cause further activation. In the above-described example, the activation is caused under the condition of the laser energy density lower than that for melting the silicon (Si) substrate. Therefore, the impurity profile corresponds to the diffusion in the high-temperature ultra short-time annealing. In the resultant impurity profile, it is impossible to independently control the profile of the high concentration region and that of the low concentration region. According to the manner in the above-described example, the activation of the implanted impurities can be realized while reducing the influence of the TED as much as possible, and the activation of the junction can be realized while maintaining the profile form just after the ion implantation. However, the source-drain junction formed based on the impurity profile just after the ion implantation is no longer sufficient to achieve the performance advancement of the hyperfine MOS with a gate length of, for example, 50 nm or shorter, and the highly concentrated, box-shaped impurity profile capable of realizing the junction depth of 30 nm or smaller and the sheet resistance of several hundreds Ω/□ or lower is indispensable in the future. More specifically, more abrupt impurity profile than the impurity profile just after the ion implantation is required.

### SUMMARY OF THE INVENTION

Meanwhile, as a technique to obtain the highly concentrated, box-shaped impurity profile, the technique performed in the following manner is conceivable in principle. That is, a region positioned at a predetermined depth within the junction is selectively melted and liquidized by irradiating a laser, and then, rapidly solidified. Since the ultra-short wavelength laser irradiation is attenuated within several tens nm in the Si substrate and the absorption coefficient of the amorphous layer is larger in comparison to that of the single crystal layer, the appropriate setting of the laser energy and the pulse width makes it possible to selectively melt and liquidize only the amorphous layer without heating the substrate. In this manner, it is also possible to selectively activate only the ion-implanted amorphous layer without heating the inside of the single crystal substrate. It is well known that the diffusion velocity of impurities in the liquid phase is about 10,000,000 times higher than that in the solid phase, and the impurity profile in the liquidized region is approximately uniform in the depth direction, and thus, the box-shaped profile can be realized. Since the melting limit of the impurity is also determined based on the liquefaction temperature, the carrier concentration in the box-shaped profile can be made almost equal to the impurity concentration. As a result, it is possible to obtain the resistance lower than that obtained in the shallow junction based on the above-described short-time high-temperature annealing. For example, even if the junction depth is further reduced to 20 nm in the P+N junction, the sheet resistance of 300 Ω/□ can be realized, that is, it is possible to reduce the sheet resistance to 0.2 times or lower the sheet resistance in the short-time high-temperature annealing. The impurity profile in the low concentration region which is not melted is almost the same as that before the laser irradiation.

However, the inventors have found out that the following problems exist in the technique using the selective melting and liquidation by the laser irradiation.

That is, in the structure in which the region to be melted is adjacent to a gate electrode via a gate insulator, the laser irradiation to melt the impurity-implanted region causes the damages or the decomposition of the adjacent gate insulator. The leak current through the gate electrode is increased due to the decomposition of the gate insulator, and in an extreme case, even the short-circuit between the gate electrode and the channel is observed. As a result, the production yield is extremely reduced. The reduction of the production yield can be solved to some extent by the strict control of the laser irradiation conditions. However, the allowable range of the irradiation condition is limited in an extremely narrow range due to the variation of the laser output and the deterioration of the equipment with time, and thus, such a technique is still far from practical use.

An object of the present invention is to provide a technique capable of improving the reliability of a semiconductor device having a field effect transistor.

The above and other objects and novel characteristics of the present invention will be apparent from the description and the accompanying drawings of this specification.

The typical ones of the inventions disclosed in this application will be briefly described as follows.

That is, an aspect of the present invention is a method of manufacturing a semiconductor device wherein, in a source-drain region of a field effect transistor, after a region apart from a gate electrode of the field effect transistor is amorphized, the amorphized region is selectively melt and liquidized by the laser irradiation, and then, the region is recrystallized.

Also, another aspect of the present invention is a method of manufacturing a semiconductor device, wherein the selective amorphization of a desired region, the selective and instantaneous melting and liquefaction of the amorphized region, and the crystal growth by the re-solidification from the liquid phase by the combined use of high dose implantation and amorphized ion implantation are used in the formation of a diffusion layer for a source and drain.

### BRIEF DESCRIPTIONS OF THE DRAWINGS

FIG. 1 is a sectional view showing the principal part of a semiconductor device according to an embodiment of the present invention in the course of the manufacturing process;

FIG. 2 is a sectional view continued from FIG. 1, which shows the principal part of a semiconductor device in the course of the manufacturing process;

FIG. 3 is an enlarged sectional view showing the principal part of FIG. 2;

FIG. 4 is a sectional view continued from FIGS. 2 and 3, which shows the principal part of a semiconductor device in the course of the manufacturing process;

FIG. 5 is a sectional view continued from FIG. 4, which shows the principal part of a semiconductor device in the course of the manufacturing process;

FIG. 6 is a sectional view continued from FIG. 5, which shows the principal part of a semiconductor device in the course of the manufacturing process;

FIG. 7 is a sectional view continued from FIG. 6, which shows the principal part of a semiconductor device in the course of the manufacturing process;

FIG. 8 is a sectional view continued from FIG. 7, which shows the principal part of a semiconductor device in the course of the manufacturing process;

FIG. 9 is a sectional view showing the principal part of a semiconductor device according to another embodiment of the present invention in the course of the manufacturing process;

FIG. 10 is a sectional view continued from FIG. 9, which shows the principal part of a semiconductor device in the course of the manufacturing process;

FIG. 11 is a sectional view continued from FIG. 10, which shows the principal part of a semiconductor device in the course of the manufacturing process;

FIG. 12 is a sectional view continued from FIG. 11, which shows the principal part of a semiconductor device in the course of the manufacturing process;

FIG. 13 is a sectional view showing the principal part of a semiconductor device according to another embodiment of the present invention in the course of the manufacturing process;

FIG. 14 is a sectional view continued from FIG. 13, which shows the principal part of a semiconductor device in the course of the manufacturing process;

FIG. 15 is a sectional view showing the principal part of a semiconductor device according to another embodiment of the present invention in the course of the manufacturing process;

FIG. 16 is a sectional view continued from FIG. 15, which shows the principal part of a semiconductor device in the course of the manufacturing process;

FIG. 17 is a sectional view showing the principal part of a semiconductor device according to another embodiment of the present invention in the course of the manufacturing process;

FIG. 18 is a sectional view continued from FIG. 17, which shows the principal part of a semiconductor device in the course of the manufacturing process;

FIG. 19 is a sectional view showing the principal part of a semiconductor device according to another embodiment of the present invention in the course of the manufacturing process;

FIG. 20 is a sectional view continued from FIG. 19, which shows the principal part of a semiconductor device in the course of the manufacturing process;

FIG. 21 is a sectional view showing the principal part of a semiconductor device according to another embodiment of the present invention in the course of the manufacturing process;

FIG. 22 is a sectional view showing the principal part of a semiconductor device according to still another embodiment of the present invention in the course of the manufacturing process; and

FIG. 23 is a graphical representation showing the relationship of a laser energy density and a sheet resistance, in which the case where indium is introduced into a diffusion layer and the case where indium is not introduced into a diffusion layer are compared.

### DESCRIPTION OF THE PREFERRED EMBODIMENTS

In the embodiments described below, the present invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of an element (including number of pieces, values, amount, range, or the like), the number of the element is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle.

Similarly, in the embodiments described below, when the shape of the components, the positional relation thereof, and the like are mentioned, the substantially approximate and similar shapes and the like are included therein unless otherwise stated or except the case where it can be conceived that they are apparently excluded in principle. This condition is also applicable to the numerical value and the range described above.

Also, components having the same functions are denoted by the same reference symbols throughout the drawings for describing the embodiment and the repetitive description thereof is omitted.

Also, in the following embodiments, a MISFET (Metal Insulator Semiconductor Field Effect Transistor) to be representative of the field effect transistor is abbreviated as MIS, a p channel MISFET is abbreviated as an nMIS, and an n channel MISFET is abbreviated as a pMIS. Note that a MOSFET is a transistor having a gate insulator comprised of a silicon oxide (SiO₂) film or the like, and the MOSFET is included in a lower concept of the MIS.

(First Embodiment)

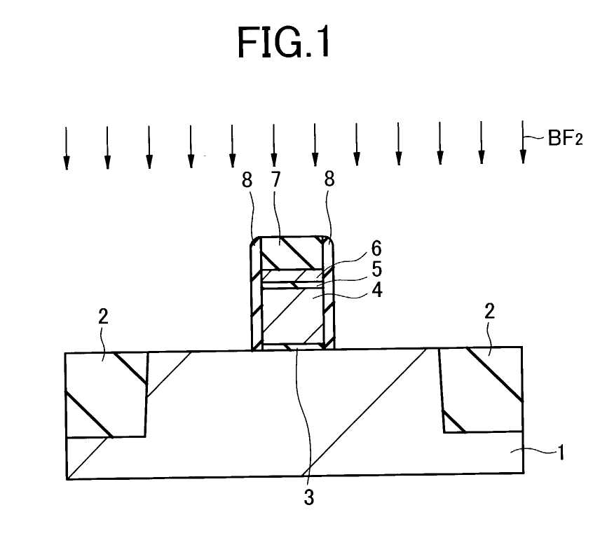

In the technique for forming a shallow junction for a source and drain based on the ion implantation and the subsequent short-time high-temperature annealing process, which is widely used in the current manufacturing technology of a semiconductor device having a MIS, the advancement of the shallow junction required in the scaling law for the miniaturization of the MIS has been reaching its limit. An object of this embodiment is to conquer the present situation and to realize a low-resistance diffusion layer even though it has the shallow junction. More specifically, an object of this embodiment is to realize a shallow diffusion layer for a source and drain extending in a transverse direction and having a box-shaped impurity profile, without causing the increase of the junction depth due to the heat diffusion of the ion implanted region. With the above-described box-shaped impurity profile, the solid solubility of the impurity is increased and the activation rate is largely increased. It is also one of the objects of this embodiment to simultaneously achieve the reduction of the source-drain series resistance and the reduction of the punch through by realizing the low-resistance, box-shaped, high concentration impurity diffusion layer with a shallow junction. The method of manufacturing a semiconductor device according to the first embodiment will be described below in detail with reference to FIGS. 1 to 8.

FIGS. 1 to 8 are sectional views showing the principal part of a semiconductor device according to the first embodiment in the course of the manufacturing process. First, as shown in FIG. 1, a semiconductor substrate (hereinafter, simply referred to as substrate) 1 made of single crystal silicon (Si) (orientation (100), n conductivity type, and about 20 cm diameter) is prepared, and device isolation regions (hereinafter, simply referred to as isolation region) 2 for defining active regions are formed in the substrate 1 with the conventional technique. Thereafter, n-type ions for adjusting the concentration of the substrate are implanted and the drive-in thermal treatment is performed to the substrate 1, and then, the ion implantation for adjusting the threshold voltage and the activation annealing treatment are performed with the conventional technique. Thereafter, the substrate 1 is subjected to the thermal oxidation process to form a thermally oxidized film with a thickness of about 1.8 nm. Then, the surface of the film is nitrided with nitrogen oxide (NO) gas, thereby forming and laminating a nitride film with a thickness of about 0.2 nm, and the nitride film is to be a gate insulator 3. The nitride film has a relative dielectric constant higher than that of the thermally oxidized silicon film, and the optically measured thickness of the nitride film electrically equivalent to the thermally oxidized silicon film is about twice as large as that of the thermally oxidized silicon film.

Subsequently, a polycrystalline silicon film 4 doped with high concentration boron (B) is deposited to a thickness of about 100 nm on the gate insulator 3 by the chemical vapor deposition method, and then, a silicon oxide film 5 with a thickness of about 2 nm, a conductive film (first film) 6 with a thickness of about 15 nm made of aluminum, and a silicon oxide film (first film) 7 with a thickness of about 45 nm are sequentially laminated on the silicon film 4 in this order from below. The silicon oxide film 5 has a function to prevent the reaction between the polycrystalline silicon film 4 and the conductive film 6. Also, the conductive film 6 and the silicon oxide film 7 have a function to increase the reflectance of the laser in the laser irradiation process described later. In addition, the silicon oxide film 7 has a function to protect the conductive film 6 formed below in the laser irradiation process described later. Thereafter, the laminated films are patterned by the use of the electron beam lithography. In this manner, a gate electrode having a gate length of about 60 nm and comprised of the polycrystalline silicon film 4 is formed.

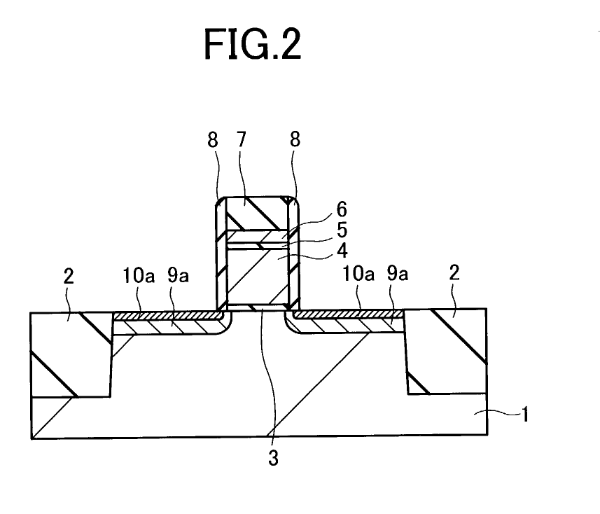

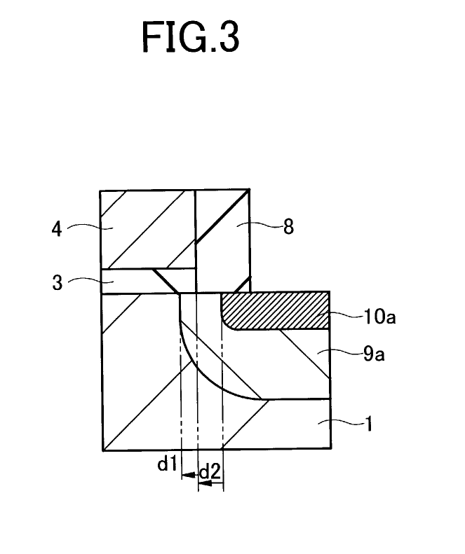

Next, a silicon oxide film with a thickness of about 8 nm is deposited over the entire surface, and an anisotropic dry etching treatment is performed so as to selectively leave the silicon oxide film on the sidewall of the polycrystalline silicon film 4 for a gate electrode. In this manner, a first gate sidewall insulator (sidewall insulator, first sidewall insulator) 8 is formed. In this state, ions of boron difluoride (BF₂) are implanted under the conditions of, for example, acceleration energy of 2 keV, and dose amount of 5×10¹⁵/cm². By the above-described ion implantation, p-type diffusion layers (diffusion layer or first diffusion layer) 9a and 9a for a source and drain having low impurity concentration are formed on both sides of the polycrystalline silicon film 4 for a gate electrode in the main surface (device forming surface) of the substrate 1 as shown in FIG. 2. In this case, the highest impurity concentration of the diffusion layer 9a is, for example, lower than about 1×10²⁰/cm³. In the regions of the p-type diffusion layers 9a and 9a for a source and drain, an amorphous layer (amorphous layer or first amorphous layer) 10a is formed with a depth of about 10 nm from the main surface of the substrate 1. According to the result of the secondary ion mass spectroscopy of a sample separately formed by the ion implantation under the same conditions as those in the above-described ion implantation, the lowest impurity concentration for forming the amorphous layer 10a is, for example, about 1×10²⁰/cm³. Also, according to the observation of the cross section of the sample by the use of a transmission electron microscopy, the pn junction portion of the p-type diffusion layer 9a for a source and drain on the side of the gate electrode reaches the position immediately below the edge portion of the polycrystalline silicon film 4 for forming the gate electrode, and the pn junction portion is overlapped with a part of the polycrystalline silicon film 4 with the portion equivalent to the length d1 as shown in FIG. 2 and FIG. 3 which is an enlarged sectional view showing the principal part of FIG. 2. Meanwhile, the edge portion of the amorphous layer 10a on the side of the gate electrode extends up to about 2 nm in a direction from the first gate sidewall insulator 8 to the gate electrode (transverse direction in FIGS. 2 and 3), but it does not reach the position immediately below the edge portion of the polycrystalline silicon film 4 for forming the gate electrode. More specifically, the edge portion of the amorphous layer 10a on the side of the gate electrode is apart from the edge portion of the polycrystalline silicon film 4 for forming the gate electrode by the length d2.

As described above, the first embodiment does not use the structure in which the amorphous layer 10a formed by the ion implantation contacts to the gate electrode via the gate insulator 3. For the achievement of the increase of a current and improvement in the punch through resistance in the MIS, such a structure is used that the positional relationship in the transverse direction between the amorphous layer to be recrystallized and the edge portion of the gate electrode and that between the diffusion layer with low impurity concentration and the edge portion of the gate electrode can be controlled. Since the transverse expansion of the low concentration region in the diffusion layer for a source and drain functions to cause the punch through, the optimization of the transverse expansion of the low concentration region in the diffusion layer for a source and drain is also important. That is, the structure capable of providing the high performance hyperfine MIS is employed, in which the short channel effect in the hyperfine MIS is reduced, the variance of the threshold voltage relative to the change in the gate length is small, and the large current output is enabled in spite of low power supply voltage. More specifically, when forming the diffusion layer 9a for a source and drain, instead of using the gate electrode as an ion implantation mask, the first gate sidewall insulator 8 is selectively formed on the sidewall of the gate electrode, and then, the ion implantation for forming the diffusion layer 9a for a source and drain is performed with using the gate electrode and the first gate sidewall insulator 8 as an ion implantation stop mask.

Furthermore, the thickness of the first gate sidewall insulator 8 is determined so that the edge portion of the amorphous layer 10a formed by the ion implantation on the side of the gate electrode reaches the position immediately below the first gate sidewall insulator 8 but not extends further toward the gate electrode, and the diffusion layer 9a for a source and drain is extended to the position immediately below the gate electrode. For the improvement of the punch through characteristics, the junction depth of the diffusion layer 9a is made as shallow as possible. According to the observation of the cross section by the use of a transmission electron microscopy, the ratio of the transverse expansion of the amorphous layer 10a formed by the ion implantation to the expansion in the depth direction in a mask region (gate electrode side) is lower than 20%, that is, about 15%. For example, in the case where the junction depth of 30 nm with the impurity concentration of the substrate 1 of 1×10¹⁸/cm² is to be realized under the conditions of the p+n junction formation by the BF₂ ion implantation, that is, the acceleration energy of 3 keV and the dose amount of 1×10¹⁵/cm², the amorphous layer 10a with a thickness of about 8 nm is formed in the depth direction, and at most about 2 nm of the semiconductor surface region is amorphized in the transverse direction toward the lower portion of the ion implantation mask. Therefore, when the first gate sidewall insulator 8 has a thickness of about 3 nm, it is possible to isolate the amorphous layer 10a in the diffusion layer for a source and drain to be melted by the laser irradiation described later from the gate electrode, and thus, the defects due to the influence of the melting process can be removed. As described above, the thickness of the first sidewall insulator 8 should be set on the basis of the conditions capable of avoiding the influence of the melting process, and on the other hand, the thickness of the first sidewall insulator 8 should be set so that the region to be melted is positioned as near the gate electrode as possible so as to achieve the current increase in the MIS by reducing the series resistance component (series resistance component between the source and drain) which cannot be controlled by the gate potential to the lower limit.

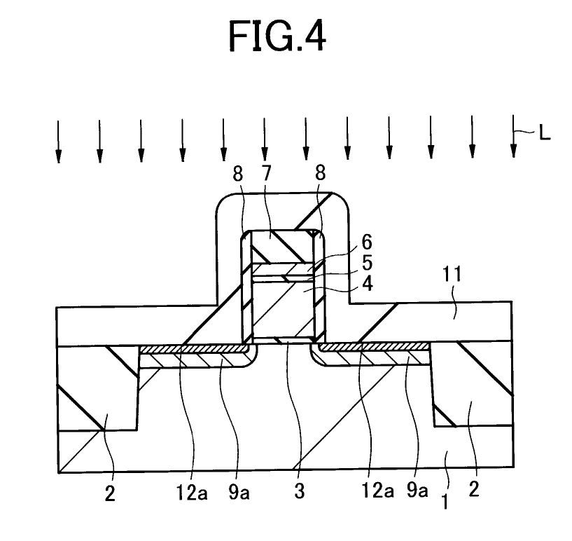

Subsequently, as shown in FIG. 4, a silicon oxide film 11 with a thickness of about 45 nm is deposited over the entire surface of the substrate 1 by the plasma assisted deposition method at a low temperature of about 400° C. Then, a laser L is irradiated to the main surface of the substrate 1 by the use of the XeCl gas laser equipment under the conditions of the wavelength of 308 nm, the half maximum full width of pulse of 30 ns, and the energy density of 0.75 J/cm². The amorphous layer 10a is instantaneously melted by the irradiation of the laser L and then recrystallized to be a p-type diffusion layer (first region) 12a having a box-shaped profile in section, which contains the impurity at a relatively high concentration in comparison to the diffusion layer 9a. It is known that the diffusion velocity in the liquidized silicon region is about 10,000,000 times higher than that in the solid phase. Also, in the case where the amount of time to melt and liquidize is extremely short, that is, about several tens ns, the temperature rise in the substrate region immediately below the melted region is small enough to be ignored in terms of the impurity diffusion due to the balance between the heating and heat radiation. Therefore, the impurity in the region re-solidified from the liquid phase region forms a box-shaped flat impurity profile extending in the depth direction, and approximately the same impurity profile as that before the annealing treatment is maintained in the region positioned immediately below the melted region. In the first embodiment, boron (B) used as an impurity is distributed again during the melting process so as to make the concentration in the melted region to be uniform, that is, about 5×10²⁰/cm³, and the thickness thereof is about 15 nm. The sheet resistance is, for example, 350 W/cm. The impurity profile in the p-type diffusion layers 9a and 9a for a source and drain positioned below the high concentrated flat-profiled impurity region remains almost unchanged even after the laser irradiation process. Rather, the profile shows the movement to the surface side, and p-type diffusion layers 9a and 9a for a source and drain having the box-shaped, high concentration profile and extending in the depth direction are obtained. The transverse expansion of the melted diffusion layer 12a and the impurity profile thereof cannot be directly observed. However, judging from the distribution of the bubble-like defects generated in the boundary of the melted region, it is estimated that the transverse expansion of the diffusion layer 12a extends about 4 nm from the edge portion of the first gate sidewall insulator 8 toward the gate electrode at the bottom of the first gate sidewall insulator 8, but not reaches the position below the gate electrode 4.

As a technique to selectively and instantaneously melt only the amorphous layer 10a, the laser irradiation by the use of the gas excited laser, for example, XeCl or KrF is used in the first embodiment. The wavelength of the XeCl is 308 nm, and that of the KrF is 248 nm. It is desirable to use the equipment capable of obtaining the half maximum full width of pulse of about several tens ns in order to prevent the heat generation at the position immediately below the melted layer and around it as much as possible. Instead of the irradiation of the continuous-wavelength beam by the use of the ark lamp or the like, the irradiation of the single-wavelength laser is used as a technique to selectively and instantaneously melt only the amorphous layer 10a because it is necessary to control the film thickness and cover a film at each desired portion on the substrate surface so as to control the reflectance and the absorption ratio to the irradiated light and to enable the selective control of the melted region and the region for preventing the temperature rise.

In the case where the region to be melted by the laser irradiation is limited to the desired regions and the temperature rise in the adjoining region can be controlled within the permissible temperature range, the laser irradiation method is an ideal technique for forming a low-resistance source and drain with a shallow junction. Note that the laser irradiation heat treatment and the thermal treatment not to melt after the re-crystallization of the amorphous region by the low-temperature annealing are not used in the first embodiment.

The equipment used in this laser irradiation usually has its own maximum irradiation area, for example, about 4 mm □ or 0.4 mm×200 mm, and the current equipment is unable to perform the irradiation to the entire main surface of the substrate 1 or irradiation to each of the chips. Therefore, it is indispensable to establish the technique capable of minimizing the influence of the overlapped irradiation in the peripheral region of the irradiation. Therefore, although the irradiation to be performed in each portion is one shot, since the irradiation area is 3×3 mm², the irradiation to the entire surface is performed so that regions with the maximum energy density of 95% or lower are overlapped with each other.

Also, it is difficult to limit the irradiation area of the laser L only to the diffusion layer for a source and drain, and thus, the irradiation to the part of the gate electrode is also inevitable. The gate electrode is formed also on the above-described isolation region separated from the substrate 1 by the thick thermal oxide film. However, since the thermal conductivity of the thick oxide film in the isolation region is about 100 times larger than that of the single crystal silicon, the heat generated by the laser irradiation to the isolation region is difficult to be radiated and released via the substrate 1 due to the interference of the thick thermal oxide film in the isolation region. Therefore, the laser irradiation should be performed under the conditions that the laser energy and the pulse width are set so that defects such as deformation, deterioration, and disappearance of the gate electrode and the gate insulator 3 due to the heat accumulation in the gate electrode can be prevented, and that only the amorphous layer 10a for a source and drain can be liquidized and activated.

Also, in the first embodiment, in order to protect the gate electrode and the gate insulator 3 from the temperature rise due to the laser irradiation process, a stacked film comprised of an electrode material film such as the polycrystalline silicon film 4, the thin insulator 5, the conductive film 6 made of aluminum, and the thin silicon oxide film 7 is patterned and processed in the pattern formation of the gate electrode. The uppermost silicon oxide film 7 can be omitted when desired. Aluminum is used as a material of the conductive film 6. This is because a short wavelength laser having wavelength of, for example, 308 nm or 248 nm is used in the irradiation process by the laser L and aluminum is a material having the largest reflectance to such short wavelength lasers. In the case where the conductive film 6 made of aluminum with a thickness of about 15 nm is provided to the laser with the above-described wavelengths, the relative intensity by the laser irradiation can be attenuated to about 10%, and the optical constants of the materials provided below become ignorable.

Also, in the first embodiment, the thickness of the uppermost silicon oxide film 7 is set about 45 nm, and after the ion implantation with using the gate electrode having the stacked film structure as an implantation stop mask, a silicon oxide film 11 with a thickness of about 45 nm is further deposited over the entire surface thereof. This silicon oxide film 11 has a function as a protection film to the laser L as well as a function to selectively form a reflective region and an anti-reflective region for the laser L. For example, in the case where the silicon oxide film 11 is deposited in the above-described manner, 30% reflectance to the irradiation of the laser L with the wavelength of 308 nm can be obtained on the substrate 1, and 91% reflectance to the same irradiation can be obtained on the gate electrode having the stacked film structure including the conductive film 6 made of aluminum and the silicon oxide film 7. More specifically, it is possible to obtain the reflective effect on the gate electrode and to obtain the anti-reflective effect on the amorphous layer 10a. In the case where the silicon oxide film 11 is not provided, the reflectance on the amorphous layer 10a is 60%. The selective introduction of the reflective film structure or the anti-reflective film structure based on the technique of depositing the conductive film 6 and the silicon oxide films 7 and 11 makes it possible to selectively melt and activate the amorphous layer 10a without causing the deterioration of the gate electrode. Consequently, it is possible to form the low-resistance diffusion layer 9a for a source and drain having the shallow junction and to realize the MIS having the gate insulator and the gate electrode with high reliability.

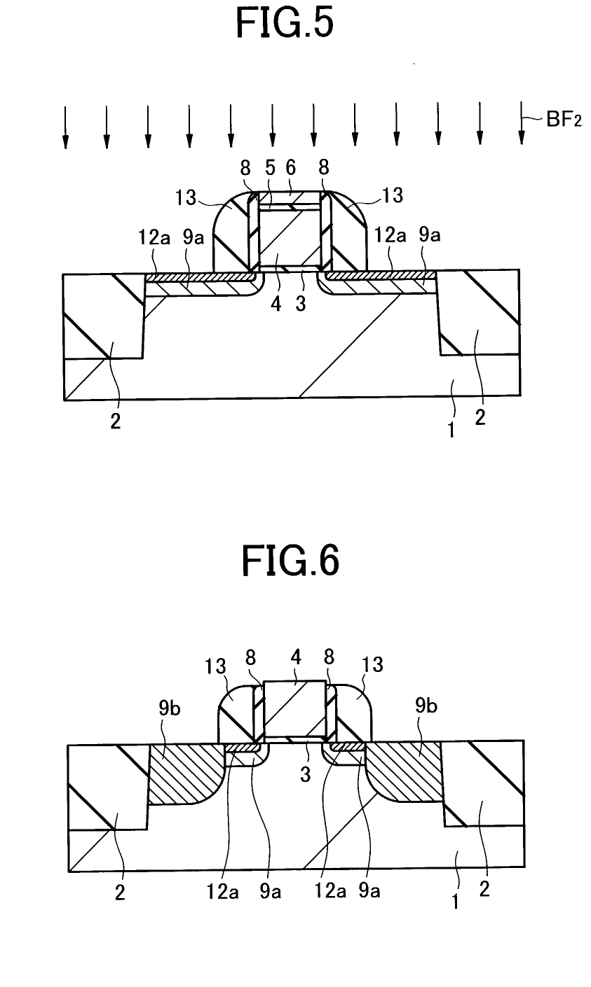

After the laser irradiation process, the silicon oxide film 11 deposited over the entire main surface of the substrate 1 is selectively removed, and the silicon oxide film 7 below the silicon oxide film 11 is also selectively removed. Subsequently, a silicon oxide film with a thickness of about 60 nm is deposited over the entire surface of the substrate 1, and then the silicon oxide film is etched back by the anisotropic dry etching. By doing so, second gate sidewall insulators (second sidewall insulator) 13 are selectively formed on the sidewalls of the polycrystalline silicon film 4 for a gate electrode and the first gate sidewall insulator 8 as shown in FIG. 5. In this state, BF₂ ions are implanted under the conditions that the dose amount is about 3×10¹⁵/cm² and the acceleration energy is about 15 keV, thereby forming p-type deep diffusion layers (second diffusion layer) 9b and 9b for a source and drain with the joint depth of about 60 nm as shown in FIG. 6. Thereafter, the conductive film 6 on the gate electrode 4 is selectively removed. Subsequently, the short-time high-temperature annealing at 950° C. for 1 second is performed to activate the implanted ions.

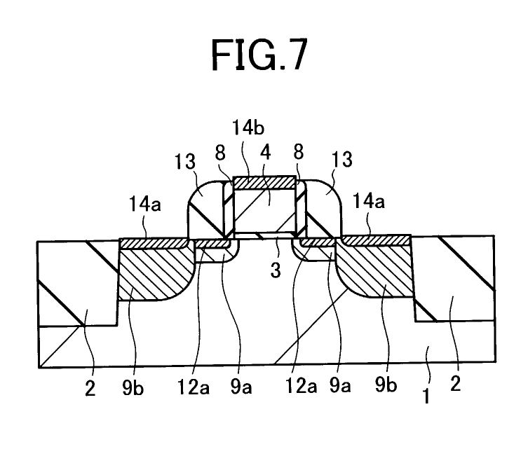

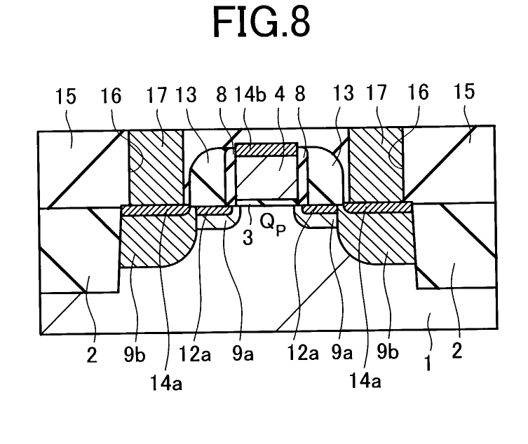

Subsequently, a refractory metal film made of, for example, cobalt (Co) is thinly deposited over the entire main surface of the substrate 1 by the sputtering method, and then, the silicide process for the substrate 1 is performed by the use of the short time annealing at 500° C. Subsequently, unreacted refractory metal film is removed by the use of mixed solution of, for example, hydrochloric acid and hydrogen peroxide solution, and as shown in FIG. 7, silicide films 14a and 14b made of cobalt silicide (CoSix) are selectively formed on the portions where the silicon is exposed. In this state, the resistance of the silicide films 14a and 14b is reduced by performing the short time annealing at about 800° C. Thereafter, a thick silicon oxide film is deposited over the entire main surface of the substrate 1 by the CVD method, and then, the surface of the silicon oxide film is planarized by the chemical mechanical polishing (CMP) method. In this manner, an insulator 15 as shown in FIG. 8 is formed.

Next, openings 16 having an approximately circular shape when viewed from above are formed in desired regions of the insulator 15 by the photolithography technique and the dry etching technique. Subsequently, after refractory metal nitride film, for example, titanium nitride (TiN) is deposited on the main surface of the substrate 1 by the sputtering method, a refractory metal film such as tungsten is deposited thereon by the CVD method or the sputtering method. Then, the laminated metal films are polished by the CMP method so as to leave the laminated metal films only in the openings 16. In this manner, plugs 17 are formed. The above-described titanium nitride film has a function as a diffusion stopper of main wiring metal. The tungsten film serves as the main wiring metal. Thereafter, according to the desired circuit configuration, wirings including a drain electrode and a source electrode are formed by the deposition of the metal film mainly made of aluminum and the pattering of the metal film. Thus, the semiconductor device having the pMIS Qp is manufactured. With respect to the impurity concentration profile in this pMIS Qp in the main surface region of the substrate 1 immediately below the gate electrode, the impurity concentration is set relatively low at the position just below the gate electrode and is gradually increased toward the inside of the substrate 1.

The junction depth of the shallow diffusion layers 9a and 9a for a source and drain in the pMIS Qp with the gate length of 60 nm according to the first embodiment manufactured through the above-described manufacturing processes is, for example, about 20 nm and that of the sheet resistance is, for example, 300 W/□. Meanwhile, in the case where the activation process is performed by the short-time high-temperature annealing at 1000° C. for 1 second, the junction depth is, for example, 30 nm and the sheet resistance is, for example, 1.9 kW/□. Therefore, the remarkable advancement in the shallow junction and the resistance reduction can be achieved in this first embodiment.

Owing to the improvement of the junction characteristics, more than 20% improvement can be achieved in the source-drain current per channel width of 1 μm in the p MIS Qp having the gate length of 60 nm under the condition of the power supply voltage of 1V, and the reduction of the leak current under the condition of the gate voltage of 0 (zero) V can be achieved. Furthermore, the threshold voltage dependence on the gate length is also reduced, and it is confirmed that the MIS having a hyperfine gate length can operate properly.

In the pMIS Qp according to this embodiment manufactured through the above-described manufacturing processes, the remarkable improvement in the production yield can be obtained in comparison to that in the technique (hereinafter, refereed to as examined technique 1) in which the activation process of the diffusion layer for a source and drain by the use of laser irradiation is performed without separating the amorphous layer 10a from the gate electrode. Except for defects found by the microscopic observation such as those in the patterns caused by foreign matters contained during the manufacturing processes, the production yield of approximately 100% can be obtained. Meanwhile, the production yield of the MIS manufactured in accordance with the examined technique is extremely low, that is, 10% or lower. The defects in the MIS manufactured in accordance with the examined technique 1 are short circuit between the gate electrode and the substrate except the defects in the patterns due to the foreign matters contained therein. It is estimated that these defects are caused by the deformation of the highly concentrated region of the diffusion layer for a source and drain immediately below the gate electrode by the laser irradiation during the melting process, and as a result, the gate insulator is destroyed and short-circuited. More specifically, in the first embodiment, since the amorphous layer 10a is separated from the polycrystalline silicon film 4 for a gate electrode, direct influences such as destroy and short circuit of the gate insulator 3 can be prevented.

According to the first embodiment, the diffusion layers 9a and 9a for a source and drain can be selectively melted and activated without causing the fatal defects of the gate electrode and the gate insulator 3 of the pMIS Qp. Also, the diffusion layers 9a and 9a for a source and drain approximately flat in the depth direction can be formed within the shallow junction, and the diffusion layer 12a having a box-shaped high impurity concentration profile can be formed. Consequently, it is possible to form the remarkably low-resistance diffusion layer for a source and drain having the shallow junction. In addition, it is possible to realize the pMIS Qp having a highly reliable gate insulator and a gate electrode. Also, the shallow junction and the resistance reduction can be achieved simultaneously, and the variance of the threshold voltage can be minimized even in the case of the miniaturization of the gate length. As described above, it is possible to provide the technique capable of achieving the ultra high integration and the high-speed operation of the pMIS Qp.

(Second Embodiment)

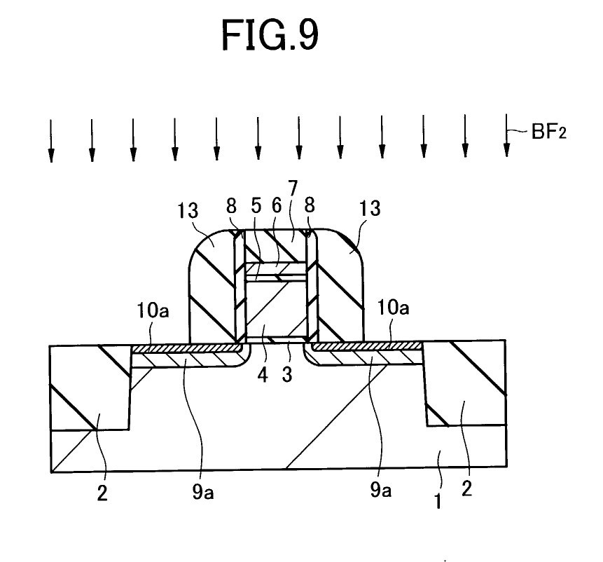

In this second embodiment, an example in which a laser irradiation process for the recrystallization of an amorphous layer and the activation of a diffusion layer is performed after forming a deep diffusion layer for a source and drain will be described with reference to FIGS. 9 to 12.

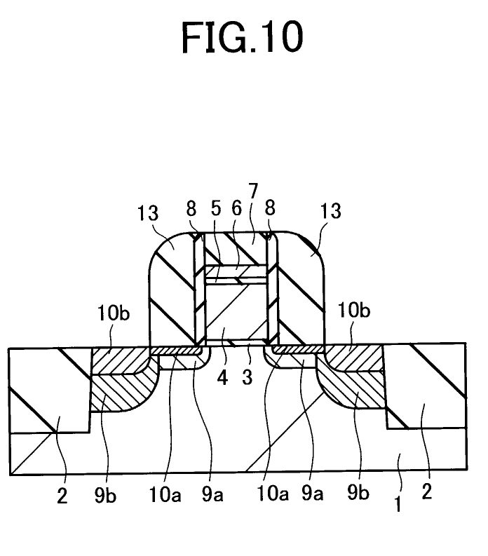

FIGS. 9 to 12 are sectional views showing the principal parts of a semiconductor device according to the second embodiment in the course of the manufacturing process. First, the same processes as those shown in FIGS. 1 and 2 described in the first embodiment are performed. Then, as shown in FIG. 9, the polycrystalline silicon film 4 for forming the gate electrode is formed and the second gate sidewall insulator 13 is formed on the sidewall of the first gate sidewall insulator 8 in the same manner as that described in FIG. 5 without performing the laser irradiation process described in the first embodiment. Subsequently, BF₂ is ion-implanted in the same manner as that described in FIG. 5, thereby forming the p-type deep diffusion layers 9b and 9b for a source and drain similar to those described above as shown in FIG. 10. The ion implantation for forming the deep diffusion layers 9b and 9b for a source and drain causes the formation of new amorphous layers (second amorphous layer) 10b. Each of the amorphous layers 10b is connected to the amorphous layers 10a in the surface regions of the shallow diffusion layers 9a and 9a for a source and drain.

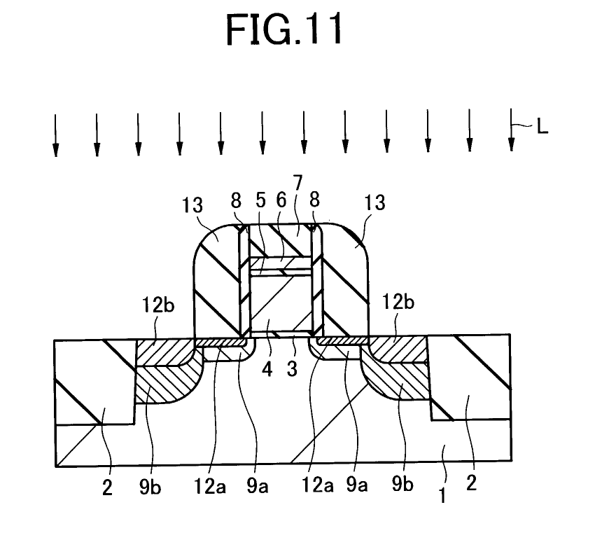

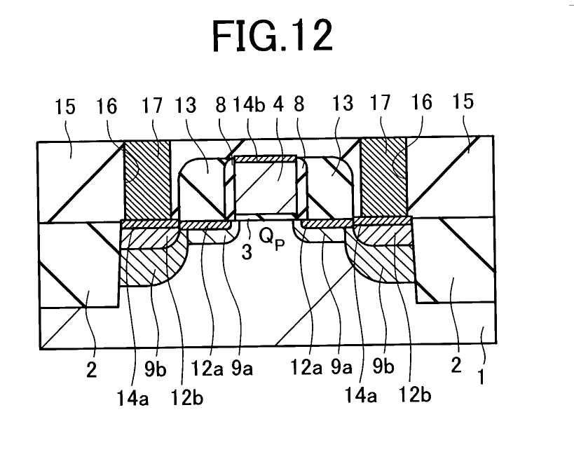

Subsequently, as shown in FIG. 11, laser is irradiated to the main surface of the substrate 1 by the use of the KrF gas laser equipment under the conditions that the wavelength is 248 nm, the half maximum full width of pulse is 20 ns, and the energy density is 0.8 J/cm². In this second embodiment, the silicon oxide film 11 having a function as a protection film to the laser irradiation is not formed. The amorphous layers 10a and 10b are instantaneously melted by the laser irradiation and then recrystallized to be p-type diffusion layers 12a and 12b. The p-type diffusion layer (second region) 12b is a region containing a relatively high concentration impurity in comparison to the diffusion layer 9b and having a box-shaped profile. More specifically, boron (B) used as an impurity is distributed again during the melting process so as to adjust the concentration in the melted region to be uniform, that is, about 5×10²⁰/cm³. The impurity concentration profiles in the p-type shallow diffusion layers 9a and 9a for a source and drain and those of the p-type deep diffusion layers 9b and 9b for a source and drain positioned below it remain almost unchanged even after the laser irradiation process. Rather, the profiles show the movement to the surface side, and the box-shaped, high concentration impurity p-type diffusion layers 12b for a source and drain extending in the depth direction are formed. The transverse expansion of the melting of the amorphous layers 10a and 10b (that is, amorphous layers 12a and 12b) does not reach the lower portion of the polycrystalline silicon film 4 for the fate electrode. More specifically, also in this second embodiment, the edge portions of the amorphous layers 10a and 10b (that is, diffusion layers 12a and 12b) on the side of the gate electrode are separated from the edge portions of the polycrystalline silicon film 4 for forming the gate electrode by a predetermined length. After the activation process of the diffusion layers 9a and 9b for a source and drain by the use of the laser irradiation, as shown in FIG. 12, the silicide films 14a and 14b, the insulator 15, the openings 16, and the plugs 17 are formed in the same manner as that of the first embodiment. Thus, the semiconductor device is manufactured. In the second embodiment, titanium silicide films are formed as the silicide films 14a and 14b. The silicide films 14a and 14b are formed in the following manner. That is, titanium (Ti) is deposited over the entire main surface of the substrate 1 to the thickness of 30 nm by the sputtering method, and the substrate 1 is heated in the nitrogen atmosphere under the conditions of 650° C. and 60 seconds, thereby selectively forming a titanium silicide film on the substrate 1 (diffusion layer 9b) and the polycrystalline silicon film 4 for a gate electrode (region on which the silicon film is exposed). Thereafter, unreacted titanium film is removed by the use of etchant containing hydrogen peroxide solution. Then, the thermal treatment for reducing the resistance of the film is performed under the conditions of 900° C. and 1 second. Note that, the silicide films 14a and 14b are not limited to the titanium silicide film, and various modifications can be made therein. For example, a silicide film of refractory metal other than the titanium silicide film such as a tungsten (W) silicide film, a molybdenum (Mo) silicide film, a cobalt (Co) silicide film, or a nickel (Ni) silicide film is also available.

According to the second embodiment, the following advantages can be obtained in addition to those achieved in the first embodiment. That is, since the p-type shallow diffusion layer 9a, the p-type deep diffusion layer 9b, and the amorphous layers 10a and 10b can be simultaneously melted and activated by the laser irradiation, the manufacturing process can be more simplified in comparison to that of the first embodiment. The source-drain current per channel width of 1 mm in the pMIS Qp having the gate length of 60 nm according to the second embodiment is 0.4 mA/mm. In other words, the increase of the current in the MIS similar to the first embodiment can be achieved.

Also, samples of the MIS in which the gate insulator 3 is replaced with an oxide film or a silicate film of, for example, aluminum (Al), titanium (Ti), tantalum (Ta), zirconium (Zr), hafnium (Hf), palladium (Pd), and lanthanum (La) are also fabricated in this second embodiment. The above-described oxide films and the silicate films are so-called high dielectric constant insulators, which have sufficiently high dielectric constant in comparison to the silicon oxide film. For example, in the MIS having a gate insulator comprised of the high dielectric constant insulator with a thickness of 2 nm in terms of the thickness of a silicon oxide film, the normal operation of the MIS with a gate length of 60 nm can be confirmed though the threshold voltage cannot be adjusted to a desired value due to the problem peculiar to the high dielectric constant gate insulator, that is, increase of the surface state. The confirmation of the normal operation indicates that the temperature in the high dielectric constant insulator just below the polycrystalline silicon film 4 for a gate electrode does not reach the temperature high enough to cause the deterioration of the film even in the laser irradiation process.

(Third Embodiment)

In the third embodiment, the case where a gate electrode of the MIS is formed of a metal film instead of semiconductor will be described.

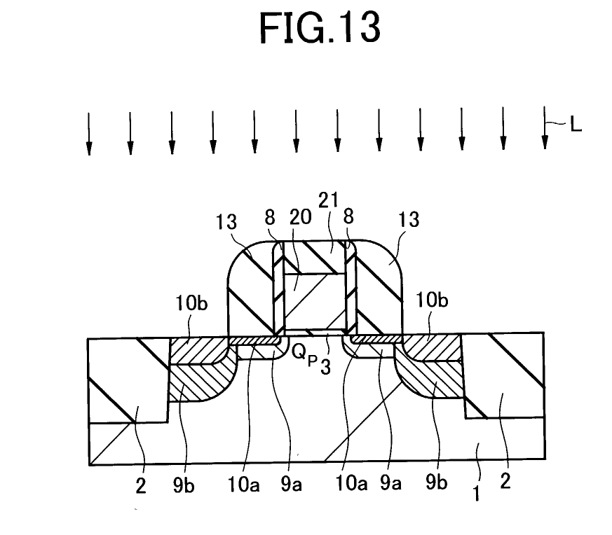

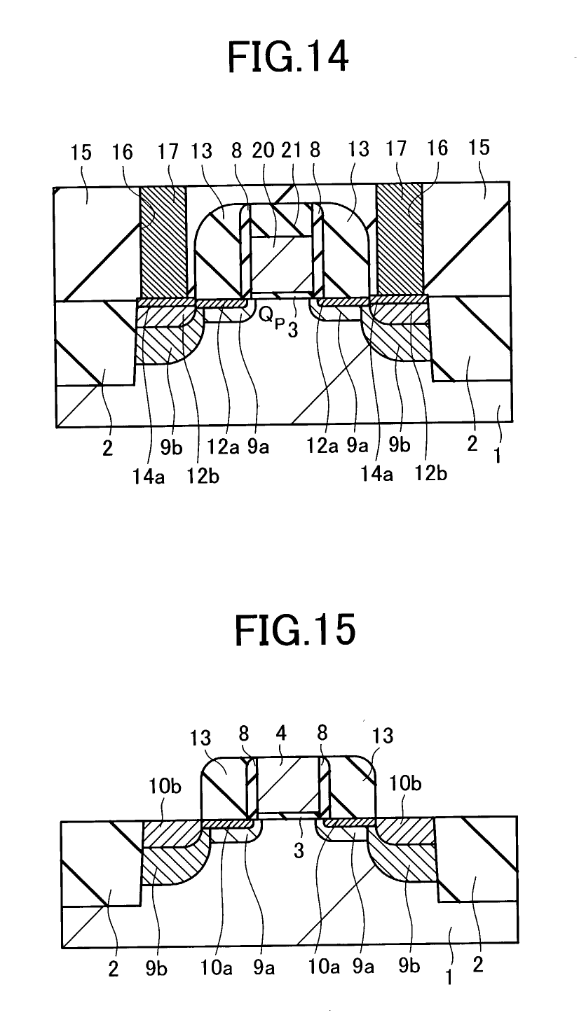

FIGS. 13 and 14 are sectional views showing the principal parts of a semiconductor device according to the third embodiment in the course of the manufacturing process. In the third embodiment, instead of the polycrystalline silicon film 4, a conductive film 20 made of low melting metal such as aluminum and aluminum alloy (aluminum-silicon-copper alloy or the like) with a thickness of 100 nm is first deposited on the gate insulator 3, and a silicon oxide film 21 with a thickness of 45 nm is deposited thereon as shown in FIG. 13. Thereafter, the laminated films are patterned by the use of the photolithography technique and the dry etching technique, thereby forming a gate electrode comprised of the conductive film 20 and the silicon oxide film 21 having a function as a gate protection film on the gate electrode. Subsequently, the first gate sidewall insulator 8, the p-type diffusion layers 9a and 9a for a source and drain, and the amorphous layer 10a are formed in the same manner as those in the first and second embodiments. Thereafter, the second gate sidewall insulator 13 is formed on the sidewall of the gate electrode and the first gate sidewall insulator 8 in the same manner as that in the second embodiment, and then, for example, BF₂ is ion-implanted, thereby forming the p-type deep diffusion layers 9b and 9b for a source and drain similar to those described above. At this time, the amorphous layer 10b is also formed in the upper portion of the deep diffusion layer 9b. Thereafter, through the laser irradiation process, the process for forming the silicide film, and the processes for forming the insulator 15, openings and plugs, the semiconductor device having the pMIS Qp is fabricated as shown in FIG. 14.

In the pMIS Qp according to the third embodiment, the activated diffusion layers 9a and 9b for a source and drain can be formed in a self-alignment manner with the conductive film 20 for a gate electrode made of low-melting metal such as aluminum, and also, damages on the gate electrode and deformation of the pattern are not observed. With respect to the electric properties, various problems concerning the deterioration of the gate insulator 3 such as leak current between the gate electrode and the substrate 1 are not observed. Therefore, in this third embodiment, a self-aligned MIS having a gate electrode made of a low-malting low-resistance material such as aluminum can be realized. As described above, the resistance of the gate electrode can be largely reduced by forming the gate electrode by the use of a metal film. In addition, in the case of the MIS having a silicon gate electrode structure, since thermal treatment is insufficient to enable to the formation of the shallow junction, the implanted impurity in the gate electrode is desaturated, which sometimes causes the problem of the depletion in the gate electrode (gate depletion). The gate depletion near the interface of the gate insulator consumes the voltage applied to the gate, which causes the increase of the effective thickness of the gate insulating film, that is, the reduction of the effective gate capacitance. These defects hinder the advancement of the performance of the hyperfine MIS. Contrary to this, since the MIS having the metal gate electrode structure can be realized in the third embodiment, the above-described problems in the hyperfine MIS having the silicon gate electrode structure can be solved.

The threshold voltage in the hyperfine pMIS Qp according to the third embodiment is transferred in a positive direction by about 0.3 V in comparison to that of a pMIS having a normal silicon gate electrode structure, and the gate is turned on when the voltage applied to the gate electrode is 0 (zero) V. This is because of the difference in the work functions of Aluminum (Al) and silicon (Si) added with boron (B). In such a circumstance, in order to solve the problems of the threshold voltage, a positive voltage is applied to the substrate 1 so as to adjust the threshold voltage to a desired value in the third embodiment. More specifically, the MIS in this embodiment is adapted to operate in the state where the substrate potential (or well potential) is controlled at a constant positive or negative potential. Although the pMIS has been described in the third embodiment, it is also possible to manufacture an nMIS through the same manufacturing process when only the conductivity type is reversed. Since the threshold voltage in the nMIS is positive, the voltage applied to the substrate 1 in order to reduce the threshold voltage should be positive voltage. In addition, according to the third embodiment, it is also possible to easily manufacture a semiconductor device having a so-called complementary MIS (CMIS) in which well diffusion regions (hereinafter, simply referred to as well region) are formed at desired portions of the substrate 1, and the nMIS or the pMIS is manufactured in each of the well regions. Also in the case of the CMIS manufactured according to the third embodiment, the threshold voltage of the CMIS can be adjusted to the desired value by applying the positive or negative potential (above-described well potential) corresponding to the source potential to each of the well regions in the substrate 1.

As another technique to solve the problems of the threshold voltage in the third embodiment, a hyperfine pMIS is separately manufactured, in which a gate electrode comprised of laminated films of a silicon (Si) film doped with highly concentrated boron (B), a titanium nitride (TiN) film, and a tungsten (W) film in this order from below is used instead of the gate electrode comprised of an aluminum film. In the manufacturing process of the pMIS having the above-described structure, in view of the prevention of the heating by the laser irradiation in the gate electrode region, the gate protection laminated film comprised of the silicon oxide film 5, the conductive film 6 made of aluminum (Al) and the silicon oxide film 7 similar to that in the first embodiment is further deposited on the laminated films comprised of silicon (Si) doped with boron (B), titanium nitride (TiN), and tungsten (W), and after the laser irradiation, the gate protection laminated film is selectively removed. The threshold voltage of the MIS having the laminated gate electrode structure comprised of silicon (Si) doped with boron (B), titanium nitride (TiN), and tungsten (W) is equal to that of the normal MIS having a silicon gate electrode, and defects due to the abnormal reaction between the silicon (Si) layer and the tungsten (W) layer via titanium nitride (TiN) such as pattern deformation and contact resistance increase are not observed, which indicates that the temperature in the gate electrode forming region is not risen to the high temperature. Consequently, the reduction of the resistance of the gate electrode can be achieved. In the laminated gate electrode structure, a tungsten (W) film is used as a metal film. However, instead of the tungsten (W) film, a metal film made of, for example, titanium (Ti), nickel (Ni), tantalum (Ta), molybdenum (mo), cobalt (Co), zirconium (Zr), or tantalum nitride (TaN) or laminated films of these metals are also available. In addition, it is not always necessary to use the silicon (Si) film doped with highly concentrated impurity as the lowermost layer.

As described above, in the third embodiment, the selective activation of the diffusion layer can be performed independently from the gate insulator 3 and the gate electrode material. Therefore, it is possible to realize the MIS having the source and drain junction self-aligned with the gate electrode by the use of the gate electrode having a laminated structure of the polycrystalline silicon film 4 and the refractory metal film and of the gate electrode structure made of a metal film only. In addition, since the diffusion layer for a source and drain can be formed in the self-alignment manner by the use of the gate electrode comprised of a metal film, it is possible to achieve the reduction of the gate resistance and to fundamentally solve the problems in the hyperfine MIS caused when using the silicon gate, for example, reduction of the effective gate capacitance caused by the depletion in the vicinity of the interface of the gate insulator and the leakage of the impurities from the gate electrode to the substrate. Consequently, the increase of the current in the hyperfine MIS and the reduction of the operating voltage of the same can be realized.

(Fourth Embodiment)

In the fourth embodiment, a method for reducing or preventing the breakage of the gate electrode by the laser irradiation process will be described in which an amorphous layer is indirectly melted and recrystallized via a predetermined metal film deposited over the substrate 1.

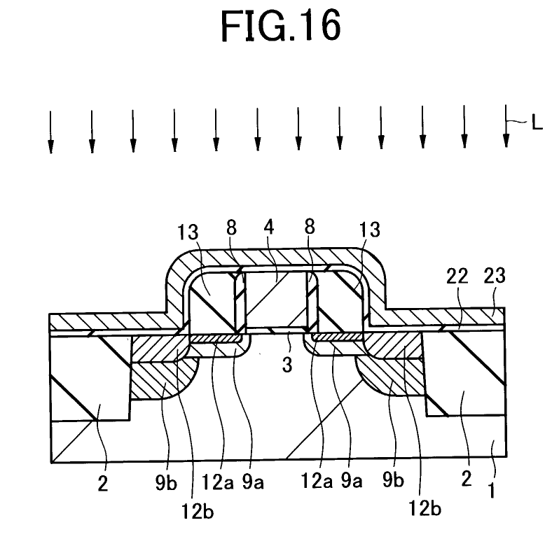

FIGS. 15 and 16 are sectional views showing the principal part of the semiconductor device according to the fourth embodiment in the course of the manufacturing process. First, the polycrystalline silicon film 4 for forming the gate electrode is patterned as shown in FIG. 15. In the fourth embodiment, the single film of the polycrystalline silicon film 4 is patterned without depositing the silicon oxide film 5 and the conductive film 6. The silicon oxide film 7 formed on the polycrystalline silicon film 4 is not always necessary. In this case, the silicon oxide film 7 is not formed. Subsequently, the first gate sidewall insulator 8, the p-type shallow diffusion layers 9a and 9a for a source and drain that include the amorphous layer 10a, the second gate sidewall insulator 13, and the p-type deep diffusion layers 9b and 9b for a source and drain with the junction depth of about 60 nm that include the amorphous layer 10b are formed in the same manner as that in the second embodiment.

Next, as shown in FIG. 16, a silicon oxide film 22 with a thickness of about 2 nm and a laminated conductive film 23 comprised of a thin titanium (Ti) film (or tungsten (W) film) and a titanium nitride (TiN) film are deposited over the entire main surface of the substrate 1 in this order from below by the chemical vapor deposition (CVD) method at a low temperature of 400° C. The silicon oxide film 22 has a function to prevent the direct contact between the laminated conductive film 23 and the silicon so as to prevent the formation of a silicide film between the laminated conductive film 23 and the silicon. Subsequently, in the fourth embodiment, laser irradiation process similar to that in the second embodiment is performed. The amorphous layers 10a and 10b are melted and resolidified by this laser irradiation process to be p-type diffusion layers 12a and 12b having high impurity concentration. The laminated conductive film 23 has a function to protect the substrate 1 and the gate electrode and a function as a heat source. More specifically, the laminated conductive film 23 protects the main surface of the substrate 1 from the direct irradiation of the laser L. In addition, the laminated conductive film 23 presses the entire main surface of the substrate 1 and the gate electrode so as to inhibit the deformation of the silicon surface, and also, the laminated conductive film 23 heats the main surface of the substrate 1 by indirectly transmitting the heat absorbed from the irradiation of the laser L. In this manner, it is possible to almost evenly heat the entire main surface of the substrate 1 while reducing or preventing fatal defects such as damages on the main surface of the substrate 1 and pattern deformation in the gate electrode. It is preferable that the material of the laminated conductive film 23 has the characteristics such as high thermal conductivity, higher melting point than silicon, and high laser absorption efficiency. The above-described titanium nitride (TiN) film, the tungsten nitride (WN) film, and the tantalum nitride (TaN) film are excellent in the thermal conductivity and have higher melting point than the silicon (Si) film. Also, since these films have large internal stress, they are resistant to the melting of the amorphous layers 10a and 10b formed below them and thus they can reduce the influence on the gate electrode to the minimum. Note that the material of the laminated conductive film 23 is not limited to the above-described materials and various modifications can be made therein. For example, instead of the titanium nitride (TiN) film, a refractory metal nitride film such as a tungsten nitride (WN) film or a tantalum nitride (TaN) film can be used as the laminated conductive film 23. In addition, it is possible to reverse the order of the deposition of the titanium (Ti) film and the titanium nitride (TiN) film. Moreover, instead of the titanium (Ti) film, a silicon (Si) film can be formed as the uppermost layer of the laminated conductive film 23. In this case, the silicon film on the surface is heated and the resulting heat is transmitted to the ultra-shallow highly concentrated amorphous layer in the source and drain region via a heat conduction layer made of titanium nitride (TiN) formed below the silicon film. Then, the amorphous layer is melted and activated. In addition, it is also possible to perform the laser irradiation process after forming a silicon oxide film or an anti-reflection film made of silicon on the laminated conductive film 23.

After the above-described laser irradiation process, the laminated conductive film 23 and the silicon oxide film 22 are selectively removed. Then, the silicide films 14a and 14b, the insulator 15, the openings 16, and the plugs 17 are formed in the same manner as those in the first and second embodiments. Thus, the semiconductor device according to the fourth embodiment as shown in FIG. 12 is manufactured.

The laminated conductive film 23 is heated by the laser irradiation in the fourth embodiment, and the amorphous layers 10a and 10b are indirectly melted by this heating. Therefore, any laser source is available as long as the irradiated light is absorbed in the laminated conductive film 23, and the YAG solid laser with the wavelength of 1064 nm as well as the gas laser, for example, Xecl (wavelength 308 nm) and KrF (wavelength 248 nm) is available.

According to the fourth embodiment, the laminated conductive film 23 is heated by the laser irradiation and the amorphous layers 10a and 10b formed below the film 23 are melted and activated by the indirect heating using the heat conduction through the laminated conductive film 23, which makes it possible to achieve both the reduction or prevention of the pattern deformation of the gate electrode and the uniform heating. In addition, in the fourth embodiment, since it is unnecessary to use the reflective film structure in the process of the hyperfine gate electrode, it is possible to largely improve the process accuracy.

(Fifth Embodiment)

In the fifth embodiment, an example in which the present invention is applied to the semiconductor device having the CMIS circuit will be described.

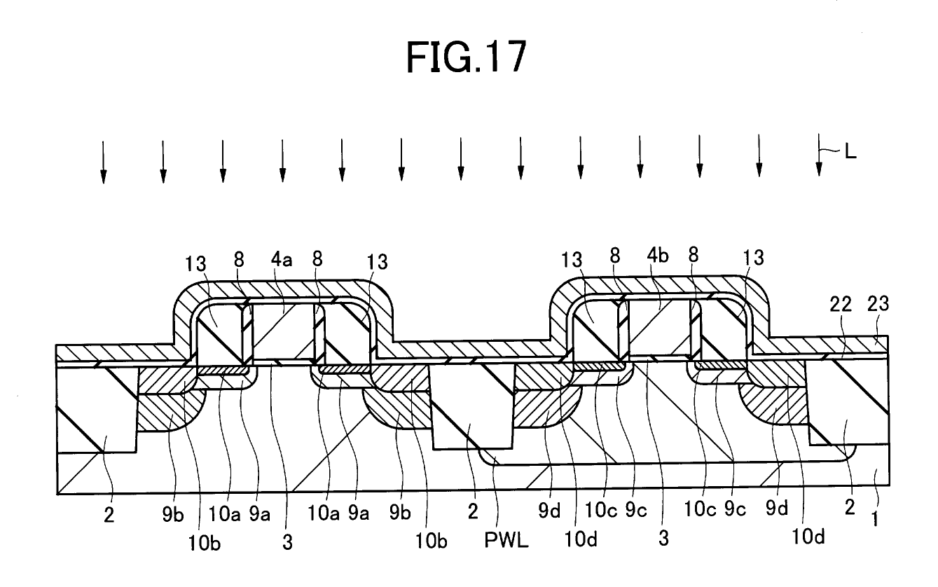

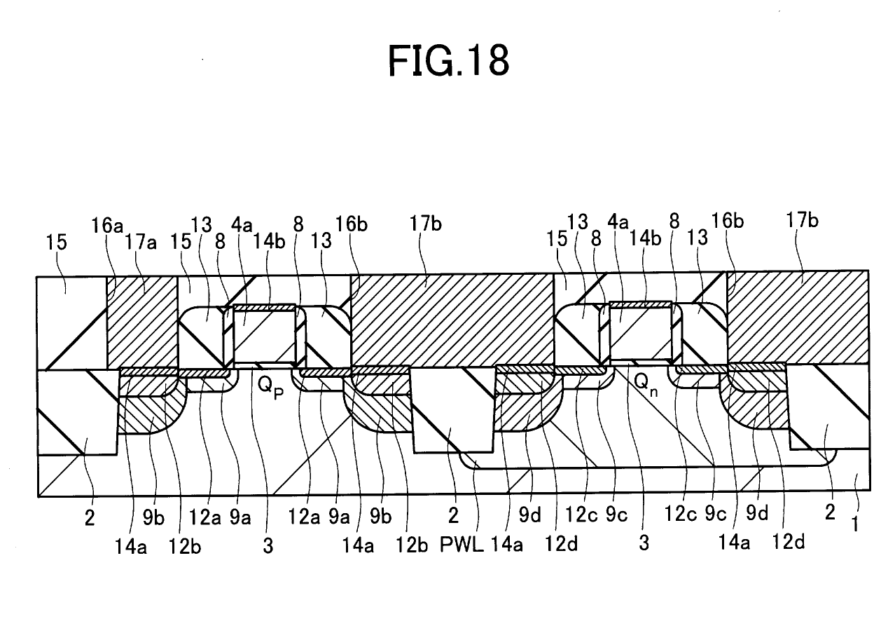

FIGS. 17 and 18 are sectional views showing the principal part of the semiconductor device according to the fifth embodiment in the course of the manufacturing process. First, as shown in FIG. 17, a p well region PWL and isolation regions 2 for defining active regions are formed in desired portions of the substrate 1, and the selective implantation of n- and p-type ions for adjusting the substrate concentration and the drive-in thermal treatment are performed, and then, the ion implantation for adjusting the threshold voltage and the activation annealing treatment are performed with the conventional technique. It is also possible to form an n well region in the n conductivity region if necessary. Subsequently, in the same manner as that of the first embodiment, the gate insulator 3 is formed over the main surface of the substrate 1, and then, a polycrystalline silicon film with a thickness of about 100 nm is deposited over the entire main surface of the substrate 1. Thereafter, in the polycrystalline silicon film, high concentration of boron (B) and phosphorus (P) are selectively ion-implanted into the pMIS forming region and the nMIS forming region, respectively. Then, after a silicon oxide film (not shown) with a thickness of about 45 nm is deposited over the main surface of the substrate 1, the silicon oxide film and the polycrystalline silicon film formed below the silicon oxide film are patterned, thereby forming a gate electrode 4a of the pMIS and a gate electrode 4b of the nMIS.

Next, after a silicon oxide film with a thickness of 8 nm is deposited over the entire surface, the anisotropic etching is performed to the silicon oxide film so as to selectively leave the silicon oxide film on the sidewalls of the gate electrodes 4a and 4b, thereby forming the first gate sidewall insulator 8. Subsequently, ions of boron difluoride (BF₂) are selectively implanted into the pMIS forming region under the conditions of the acceleration energy of 2 keV and the dose amount of 1×10¹⁵/cm², and ions of arsenic are selectively implanted into the nMIS forming region under the conditions of the acceleration energy of 3 keV and the dose amount of 1×10¹⁵/cm² with using the first gate sidewall insulator 8 and the gate electrodes 4a and 4b as an ion implantation stop mask. By the ion implantation, the p-type diffusion layers 9a and 9a for a source and drain including the amorphous layer 10a with a thickness of about 10 nm and n-type diffusion layers (diffusion layer or first diffusion layer) 9c and 9c for a source and drain including the amorphous layer (amorphous layer or the first amorphous layer) 10c are formed over the main surface of the substrate 1. The arrangement of the n-type diffusion layer 9c and the amorphous layer 10c on the side of the nMIS is the same as that of the p-type diffusion layer 9a and the amorphous layer 10a on the pMIS side. More specifically, the amorphous layer 10c is separated from the edge portion of the gate electrode 4b, and the tip portion of the diffusion layer 9c on the side of the gate electrode 4b is overlapped with the gate electrode 4b. In this case, the maximum impurity concentration of the low concentrated diffusion layers 9a and 9c is, for example, 1×10²⁰/cm³ or lower.

Next, a silicon oxide film with a thickness of 60 nm is deposited over the entire main surface of the substrate 1, and then, the anisotropic dry etching is performed to the silicon oxide film, thereby selectively forming the second gate sidewall insulators 13 on the sidewalls of the gate electrodes 4a and 4b and the first gate sidewall insulator 8. Subsequently, ions of boron difluoride are selectively implanted into the pMIS forming region under the conditions of the acceleration energy of 15 keV and the dose amount of 3×10¹⁵/cm², and ions of arsenic (As) are selectively implanted into the nMIS forming region under the conditions of the acceleration energy of 40 keV and the dose amount of 3×10¹⁵/cm² with using the second gate sidewall insulator 13 and the gate electrodes 4a and 4b as an ion implantation stop mask. The p-type deep diffusion layers 9b and 9b for a source and drain including the amorphous layer 10b and n-type deep diffusion layers (second diffusion layer) 9d and 9d for a source and drain including the amorphous layer (second amorphous layer) 10d are formed by the ion implantation.

Next, in the same manner as that of the fourth embodiment, the silicon oxide film 22 and the laminated conductive film 23 are deposited over the main surface of the substrate 1 in this order from below. Thereafter, the laser L is irradiated to the main surface of the substrate 1 in the same manner as those of the second to fourth embodiments. The amorphous layers 10a, 10b, 10c, and 10d are melted by the laser irradiation in the same manner as that in the fourth embodiment, and through the crystal growth from the liquid phase to the solid phase, the p-type diffusion layer 12a, the p-type diffusion layer 12b, the n-type diffusion layer (first region) 12c, and the n-type diffusion layer (second region) 12d, each having the box-shape and high concentration impurity profile are formed as shown in FIG. 18. The n-type diffusion layers 12c and 12d basically have the same impurity profile as those of the p-type diffusion layers 12a and 12b except that conductivity types thereof are different from each other. In this manner, the pMIS Qp and the nMIS Qn are formed. After the selective removal of the silicon oxide film 22 and the laminated conductive film 23, the insulator 15 is deposited over the main surface of the substrate 1 in the same manner as that of the first embodiment, and then, openings 16a and 16b are formed at desired positions in the insulator 15. The opening 16a having a circular shape when viewed from above and the opening 16b having a box shape when viewed from above are exemplified. Thereafter, a conductive film is buried in the openings 16a and 16b in the same manner as that of the first embodiment, thereby forming a plug 17a and wirings 17b. In this manner, the semiconductor device according to the fifth embodiment is manufactured.

According to the fifth embodiment as described above, the junction depth of the shallow diffusion layers 9c and 9c for a source and drain of the nMIS Qn with the gate length of 60 nm can be set, for example, about 20 nm, and the sheet resistance thereof can be set, for example, about 100 W/□. Also, the junction depth of the shallow diffusion layers 9a and 9a for a source and drain of the pMIS Qp can be set, for example, about 20 nm, and the sheet resistance thereof can be set, for example, about 300 W/□. As described above, in comparison to the normal activation process, much shallower junction depth and the further reduction of the resistance can be achieved. In the nMIS having the gate length of 60 nm examined by the inventors, the source-drain current per channel width of 1 mm is about 0.65 mA/mm under the condition of the power supply voltage of 1 V and the leak current under the condition of the gate voltage of 0 V is 8.2×10⁻⁹ A/mm. Meanwhile, in the nMIS Qn according to the fifth embodiment, which has the same dimensions as those of the nMIS, the source-drain current per channel width of 1 mm is about 0.8 mA/mm and the leak current under the condition of the gate voltage of 0 V is 5.6×10⁻¹⁰ A/mm. More specifically, owing to the improvement of the junction characteristics, more than 20% improvement can be achieved in the source-drain current per channel width of 1 mm, and the reduction of the leak current can be achieved. Furthermore, the threshold voltage dependence on the gate length is also reduced, and it is confirmed that the MIS having a hyperfine gate length can operate properly.

(Sixth Embodiment)

In the sixth embodiment, an example of a method for reducing the channel resistance of a MIS will be described.

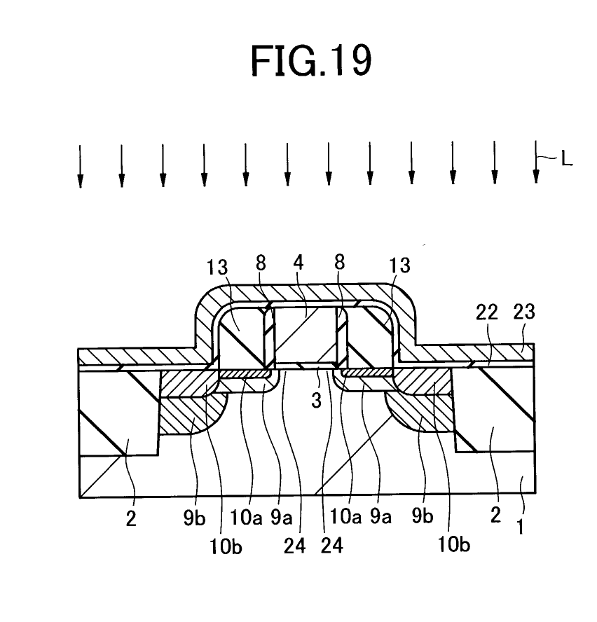

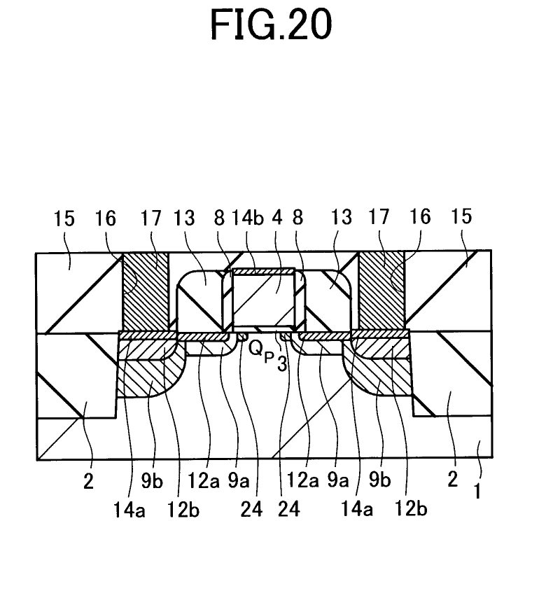

FIGS. 19 and 20 are sectional views showing the principal part of a semiconductor device according to the sixth embodiment in the course of the manufacturing process. The semiconductor device according to the sixth embodiment is almost the same as that described in the fourth embodiment. There are two differences between these semiconductor devices. First, as shown in FIG. 19, p-type diffusion layers 24 and 24 for a source and drain having relatively high concentration and ultra-shallow junction are separately formed on the substrate 1 without requiring the formation of amorphous layers. The p-type diffusion layers 24 and 24 are formed in the following manner. That is, after the patterning of the polycrystalline silicon film 4 for forming the gate electrode and before the formation of the first gate sidewall insulator 8, ions of boron difluoride (BF₂) are implanted under the conditions of the dose amount of 2×10¹⁴ /cm² and the acceleration energy of 1 keV, with using the polycrystalline silicon film 4 as an implantation stop mask. In the above-described first to fifth embodiments, since the impurity introduction process for forming the shallow diffusion layer is performed after the formation of the first gate sidewall insulator 8 on the sidewalls of the gate electrode, there is the possibility that a case may arise where the shallow diffusion layer (including a surface impurity region with the concentration of about 10¹⁹/cm³ on the surface region thereof) does not overlap the gate electrode and the diffusion layer is separated from the edge portion of the gate electrode. Since the separated region is not directly controlled by the gate field and the separated region causes the increase of the series resistance, the increase of the current in the MIS is hindered. Therefore, a technique is used in this sixth embodiment, in which the ion implantation with a middle concentration is performed in advance with using the gate electrode as an ion implantation mask before the formation of the first gate sidewall insulator 8, thereby forming the diffusion layers 24. Note that the middle concentration in the ion implantation for forming the diffusion layer 24 is preferably set to the highest possible value as long as it does not cause the amorphization. For example, surface impurity concentration of 1×10¹⁹/cm³ is suitable.

As a second difference, instead of a silicon oxide film, an aluminum oxide film to be an insulator having relative dielectric constant higher than that of a silicon oxide film is used as the first gate sidewall insulator 8. For example, oxide films, nitride films or silicate films of titanium (Ti), tantalum (Ta), zirconium (Zr), hafnium (Hf), palladium (Pd), and lanthanum (La) are available as the high dielectric constant film.

After the process of forming the diffusion layer 24 and the first gate sidewall insulator 8, the diffusion layer 9a including the amorphous layer 10a, the second gate sidewall insulator 13, the diffusion layer 9b including the amorphous layer 10b, the silicon oxide film 22, and the laminated conductive film 23 are formed in the same manner as that in the fourth embodiment. Thereafter, the laser irradiation process in the same manner as that in the fourth embodiment is performed to the main surface of the substrate 1. By doing so, the amorphous layers 10a and 10b are melted and recrystallized so as to form the diffusion layers 12a and 12b as shown in FIG. 20. Subsequently, through the processes similar to those in the fourth embodiment, the semiconductor device having a pMIS Qp according to the sixth embodiment is manufactured.

As described above, in the pMIS Qp according to the sixth embodiment, the diffusion layers 24 and 24 for a source and drain having the ultra-shallow junction are formed over the main surface of the substrate 1 so that the diffusion layers 24 overlap the edge portion of the polycrystalline silicon film 4 for forming the gate electrode. The diffusion layer 24 does not contribute to the melting by the use of the laser irradiation. However, the diffusion layer 24 has a function to reduce the series resistance in the region formed by this melting, which extends from the diffusion layer 12a for a source and drain having the box-shaped high concentration impurity profile to the channel.

Also, by the use of the first gate sidewall insulator 8 comprised of the high dielectric constant insulator, the component of gate sidewall field, so-called fringing field is more effectively applied to the main surface of the substrate 1 positioned immediately below the first gate sidewall insulator 8. More specifically, the first gate sidewall insulator 8 contributes to the increase of the hole density in the p conductivity region, and also contributes to the large current operation caused by the resistance reduction. When the settings for the conditions of the ion implantation are not optimized, the threshold voltage dependence on the gate length is deteriorated due to the increase of the junction depth. Therefore, it is necessary to pay attention to the introduction of the diffusion layers 24 and 24. Also, with respect to the configuration of the first gate sidewall insulator 8 comprised of the high dielectric constant insulator, the increase of the thickness of the first gate sidewall insulator 8 causes the increase of the fringing capacitance, which hinders the achievement of the high-speed operation. Therefore, the analysis of the operation speed performed by the inventors have found out that the thickness of the first gate sidewall insulator 8 is in the range of smaller than 10 nm and larger than 5 nm. It is unnecessary to simultaneously form the diffusion layers 24 and 24 for a source and drain having the ultra-shallow junction and the first gate sidewall insulator 8 comprised of the high dielectric constant insulator. The large current operation, in other words, high-speed operation can be achieved if either one of them is provided.

(Seventh Embodiment)

In the seventh embodiment, an example of a method of controlling a depth of an amorphous layer will be described.

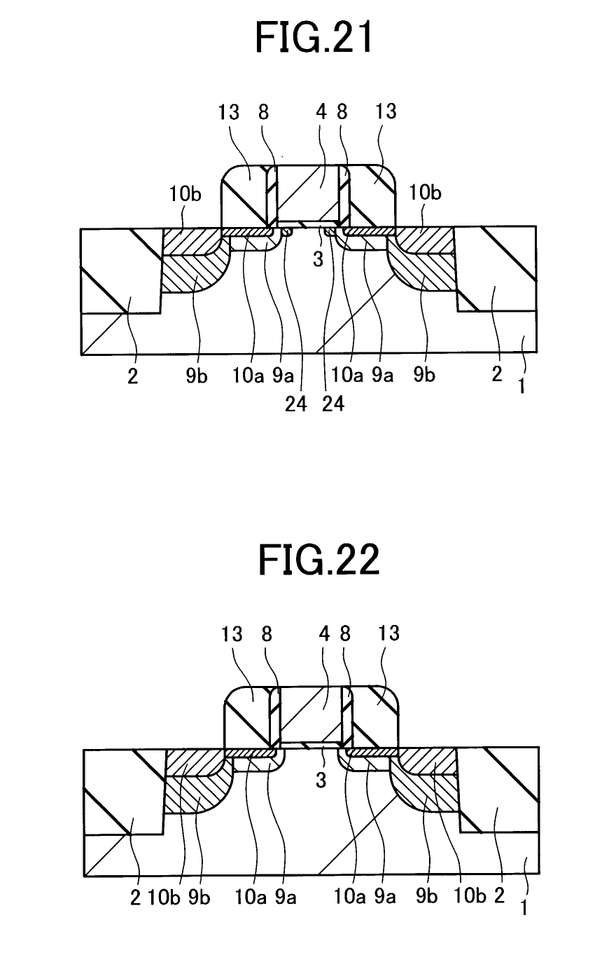

FIG. 21 is a sectional view showing the principal part of the semiconductor device according to the seventh embodiment in the course of the manufacturing process. The semiconductor device according to the seventh embodiment is almost the same as that described in the sixth embodiment. The difference between the semiconductor devices is that the amorphous layer to be melted by the laser irradiation is not formed only by the high dose ion implantation of the impurity for forming the diffusion layer such as BF₂ but by the high dose ion implantation of a material such as germanium (Ge) or silicon (Si), which does not affect the junction characteristics. In this case, the depth of a portion to be melted by the laser irradiation is controlled by controlling the depth of the amorphous layer by the use of germanium and silicon. More specifically, the amorphous layer 10a is formed by implanting the ions of germanium (Ge) into the substrate 1 under the conditions of the acceleration energy of 5 keV and the dose amount of 1×10¹⁵/cm². Thereafter, the p-type shallow diffusion layers 9a and 9a for a source and drain are formed by implanting the ions of boron (B) into the substrate 1 under the conditions of the acceleration energy of 500 keV and the dose amount of 1×10¹⁵/cm². By doing so, the amorphous layer 10a can be formed even in the boron (B) ion implanted layer, in which the amorphization is not ordinarily obtained. The above-described germanium ion implantation process can be performed after the ion implantation process for forming the shallow diffusion layer 9a for a source and drain. In the seventh embodiment, germanium (Ge) ion implantation is performed even in the formation of the deep diffusion layers 9b and 9b for a source and drain and then the amorphous layer 10b is formed. The germanium ion implantation process in this case can be performed either before or after the ion implantation process for forming the shallow diffusion layer 9a for a source and drain. Thereafter, the laser irradiation process as shown in FIG. 19 is performed in the same manner as that in the sixth embodiment to cause the selective melting and resolidification of the amorphous layers 10a and 10b. Then, the box-shaped, p-type diffusion layers 12a and 12b having the high concentration impurity profile is formed as shown in FIG. 20. In this manner, the semiconductor device according to the seventh embodiment is manufactured.

In this seventh embodiment, since the amorphous layer forming processes by the use of the high dose implantation of germanium (Ge) ions are performed before the boron (B) ion implantation (or after that), the expansion of the low concentration region due to the channeling phenomenon caused in the boron (B) ion implantation can be reduced or prevented. Also, the shallow junction of the shallow diffusion layers 9a and 9a for a source and drain can be realized, and the threshold voltage dependence on the gate length can be improved to a value capable of operating a device having a shorter channel. It is also possible to use argon (Ar) instead of germanium and silicon.

(Eighth Embodiment)

In the eighth embodiment, an example of a method of reducing the temperature in the laser irradiation process will be described.

FIG. 22 is a sectional view showing the principal part of a semiconductor device according to the eighth embodiment in the course of the manufacturing process. The semiconductor device according to the eighth embodiment is almost the same as that described in the fourth embodiment. The difference between the semiconductor devices is that impurities such as indium (In) functioning to reduce the melting point of silicon (Si) are ion-implanted into the substrate 1 immediately after (or before) the ion implantation process for forming the p-type shallow diffusion layers 9a and 9a for a source and drain and immediately after (or before) the ion implantation process for forming the p-type deep diffusion layers 9b and 9b for a source and drain. More specifically, subsequent to the ion implantation for forming the diffusion layer 9a , indium (In) ions are implanted into the substrate 1 under the conditions of the dose amount of 5×10¹⁵/cm² and the acceleration energy of 10 keV. Also, subsequent to the ion implantation for forming the diffusion layer 9b, indium (In) ions are implanted into the substrate 1 under the conditions of the dose amount of 1×10¹⁵/cm² and the acceleration energy of 20 keV. By doing so, the amorphous layer 10a containing indium (In) and boron (B) at high concentration is formed in the surface portion of the diffusion layer 9a. In addition, the amorphous layer 10b containing indium (In) and boron (B) with high concentration is formed in the surface portion of the diffusion layer 9b.

In this state, a silicon oxide film with a thickness of, for example, 45 nm is deposited on the entire main surface of the substrate 1. Thereafter, laser is irradiated to the main surface of the substrate 1 by the use of the KrF gas laser equipment under the conditions that the wavelength is 248 nm, the half maximum full width of pulse is 20 ns, and the energy density is 0.65 J/cm². In the techniques described in the second and fourth embodiments, the amorphous layers 10a daddy and 10b are not melted even by the laser irradiation process under the same conditions as described above. However, in the eighth embodiment, the amorphous layers 10a and 10b are melted and resolidified, and as a result, the high concentration impurity diffusion layers 12a and 12b (refer to FIG. 12) having the box-shaped impurity profile can be formed. The difference between the eighth embodiment and the second and fourth embodiments is that high concentration indium (In) is doped into the amorphous layers 10a and 10b. This fact indicates that the doped indium (In) functions to reduce the melting point of the amorphous layers 10 and 10b. According to the examination by the inventor, the indium ion implantation can reduce the melting point of silicon, that is, that of the substrate 1 (for example, 1414° C.) by about 150 to 200° C. More specifically, it is possible to be the melting point of the substrate 1 in the range of 1214 to 1264° C.

Subsequently, after the laser irradiation as described above, the silicon oxide film with a thickness of about 45 nm deposited before the laser irradiation process is selectively removed, and the silicide films 14a and 14b, the insulator 15, the openings 16, and the plugs 17 are formed in the same manner as that in the fourth embodiment. Consequently, the semiconductor device having the pMIS Qp according to the eighth embodiment is manufactured.

According to the eighth embodiment, the formation of the shallow junction of the highly concentrated, box-shaped impurity profile source and drain can be realized under the conditions of lower energy density in comparison to that of the fourth embodiment. By doing so, the overheating of the gate electrode region by the laser irradiation can be prevented. Therefore, fatal defects such as deterioration of the gate insulator 3 and short circuit between the gate electrode and the substrate 1 can be reduced or prevented. In addition, it is also possible to reduce or prevent the displacement and the disappearance of the gate electrode due to the heat of the laser, and thus, the reliability of the gate electrode and its periphery can be improved. Accordingly, it is possible to set large process margin, and the manufacturing process can be facilitated.

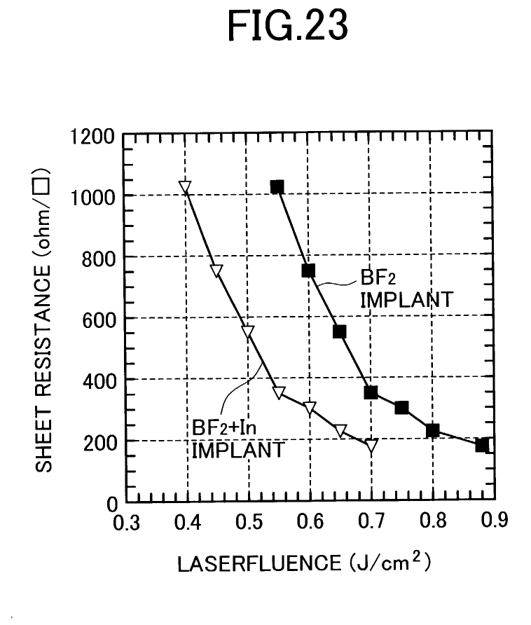

FIG. 23 shows the results of the measurements, in which the laser irradiation energy dependence relevant to the formation of the p-type diffusion layer 9a for a source based on the fourth embodiment and the laser irradiation energy dependence relevant to the formation of the p-type diffusion layer 9a for a source added with indium based on the eighth embodiment are separately examined. As is apparent from FIG. 23, the laser irradiation energy density required for the melting can be reduced to about 150 mJ/cm² by adding indium (In) to the amorphous layer. As described above, in the eighth embodiment, since it is possible to form a good diffusion layer 12a in the state where the irradiation energy of the laser is reduced, it is also possible to remove the first gate sidewall insulator 8.

More specifically, it is possible to omit the formation of the first gate sidewall insulator 8, and the p-type diffusion layers 9a and 9a for a source and drain including the amorphous layer can be formed by the ion implantation with using the polycrystalline silicon film 4 for forming the gate electrode as an implantation stop mask.

Note that the reduction of the melting temperature of the amorphous layers 10a and 10b and the reduction of the energy density in the eighth embodiment can be achieved also by means of the addition of other impurities. The same effects can be observed in the case of the addition of, for example, bismuth (Bi) and lead (Pb). Therefore, in the eighth embodiment, bismuth (Bi), lead (Pb), germanium (Ge), or antimony (Sb) is also available instead of indium (In). Also, in the case of applying the eighth embodiment to an nMIS, germanium (Ge) is suitable as a material to reduce the melting point of the substrate 1. Since germanium can be used in both the cases of the pMIS and the nMIS, germanium is also preferably applied to the case in which a pMIS and an nMIS are formed over the same substrate 1.

In the foregoing, the invention made by the inventors of this invention has been described in detail based on the embodiments. However, it goes without saying that the present invention is not limited to the above-described embodiments, and various changes and modifications of the invention can be made without departing from the spirit and scope of the invention.

For example, the first to fourth embodiments and seventh and eighth embodiments have been described with respect to the case of a pMIS. However, the same effects can be obtained even in the case of an nMIS.

Also, in the above-described embodiments, laser having a relatively long wavelength such as YAG laser (wavelength: 1064 nm) is also available as a laser used in the laser irradiation process.

In the foregoing, the case where the invention achieved by the inventor is applied to the method of manufacturing a semiconductor device having a CMIS circuit, which is a background of the invention, has been mainly described. However, the application of the present invention is not limited to this. For example, it is possible to apply the present invention to the technique for a semiconductor device having a memory circuit such as DRAM (Dynamic Random Access Memory), SRAM (static RAM) or flash memory (EEPROM: Electric Erasable Programmable Read Only Memory), to the technique for a semiconductor device having a logic circuit such as a microprocessor, and to the technique for an embedded semiconductor device in which a memory circuit and a logic circuit are provided on the same substrate.

The advantages achieved by the typical ones of the inventions disclosed in this application will be briefly described as follows.

That is, in a source-drain region of a field effect transistor, after a region apart from a gate electrode of the field effect transistor is amorphized, the amorphized region is selectively melt and liquidized by the laser irradiation, and then, the region is recrystallized. In this manner, the reliability of a semiconductor device having the field effect transistor can be improved.

What is claimed is:

1. A method of manufacturing a semiconductor device, comprising the steps of:
(a) forming a gate insulator over a main surface of a semiconductor substrate;
(b) forming a gate electrode over the gate insulator;
(c) forming a sidewall insulator on a sidewall of the gate electrode;
(d) introducing a first ion into the semiconductor substrate with using the gate electrode and the sidewall insulator as a mask, thereby forming a diffusion layer for a source and drain in the semiconductor substrate and forming an amorphous layer at a position apart from the gate electrode in a surface portion of the diffusion layer; and
(e) irradiating laser to the main surface of the semiconductor substrate, thereby selectively recrystallizing the amorphous layer.

2. The method of manufacturing a semiconductor device according to claim 1,
wherein, after the step (b) and before the step (c), the method further comprises the step of: introducing an impurity ion into the semiconductor substrate with using the gate electrode as a mask in order to form a diffusion layer having the same conductivity type as that of the diffusion layer for a source and drain.

3. The method of manufacturing a semiconductor device according to claim 1,
wherein the step (d) includes the steps of:
(d1) introducing an impurity ion for forming the diffusion layer for a source and drain; and
(d2) introducing an element ion for forming the amorphous layer.

4. The method of manufacturing a semiconductor device according to claim 3,
wherein the step (d2) of introducing the element ion is an ion implantation process of at least one of germanium and silicon.

5. The method of manufacturing a semiconductor device according to claim 1,
wherein the step (d) includes the steps of:
(d1) introducing an impurity ion in the semiconductor substrate for forming the diffusion layer for a source and drain and the amorphous layer; and
(d2) introducing an impurity ion for reducing a melting point of the amorphous layer.

6. The method of manufacturing a semiconductor device according to claim 5,
wherein the step (d2) of introducing the element ion is an ion implantation process of at least one of indium, bismuth, lead, germanium, and antimony.

7. The method of manufacturing a semiconductor device according to claim 1,
wherein the diffusion layer for a source and drain is activated by the laser irradiation process.

8. The method of manufacturing a semiconductor device according to claim 1,
wherein the step (b) includes the steps of:
(b1) depositing a semiconductor film over the main surface of the semiconductor substrate including an upper surface of the gate insulator;
(b2) forming a first film having a function to increase a reflectance of the laser over the semiconductor film; and
(b3) pattering the semiconductor film and the first film into a shape of a gate electrode.

9. The method of manufacturing a semiconductor device according to claim 8,
wherein the first film includes a conductive film made of an aluminous material.

10. The method of manufacturing a semiconductor device according to claim 8,
wherein the first film includes a laminated film formed by depositing an insulator on a conductive film made of an aluminum material.

11. The method of manufacturing a semiconductor device according to claim 10,
wherein, after the step (d), an insulator with a desired thickness is deposited over the main surface of the semiconductor substrate, and then, the laser irradiation process in the step (e) is performed.

12. The method of manufacturing a semiconductor device according to claim 1,
wherein, after the step (d), a metal film with good heat conductivity is deposited over the main surface of the semiconductor substrate via an insulator, and then, the laser irradiation process in the step (e) is performed.

13. The method of manufacturing a semiconductor device according to claim 12,
wherein the metal film with good heat conductivity is a refractory metal film or a refractory metal nitride film.

14. A method of manufacturing a semiconductor device, comprising the steps of:
(a) forming a gate insulator over a main surface of a semiconductor substrate;
(b) forming a gate electrode over the gate insulator;
(c) forming a first sidewall insulator on a sidewall of the gate electrode;
(d) introducing a first ion into the semiconductor substrate with using the gate electrode and the first sidewall insulator as a mask, thereby forming a first diffusion layer for a source and drain in the semiconductor substrate and forming a first amorphous layer at a position apart from the gate electrode in a surface portion of the first diffusion layer;
(e) after the step (d), forming a second sidewall insulator on the sidewall of the gate electrode and the first sidewall insulator;
(f) introducing a second ion for forming the same conductivity type as that of the first ion into the semiconductor substrate with using the gate electrode, the first sidewall insulator and the second sidewall insulator as a mask, thereby forming a second diffusion layer for a source and drain in the semiconductor substrate and forming a second amorphous layer in a surface portion of the second diffusion layer; and
(g) irradiating laser to the main surface of the semiconductor substrate, thereby selectively recrystallizing the first and second amorphous layers.

15. The method of manufacturing a semiconductor device according to claim 14,
wherein, after the step (b) and before the step (c), the method further comprises the step of: introducing an impurity ion into the semiconductor substrate with using the gate electrode as a mask in order to form a diffusion layer having the same conductivity type as that of the diffusion layer for a source and drain.

16. The method of manufacturing a semiconductor device according to claim 14,
wherein the step (d) includes the steps of:
(d1) introducing an impurity ion for forming the first diffusion layer for a source and drain in the semiconductor device; and
(d2) introducing an element ion for forming the first amorphous layer, and
the step (f) includes the steps of:
(f1) introducing an impurity ion in the semiconductor device for forming the second diffusion layer for a source and drain; and
(f2) introducing an element ion for forming the second amorphous layer.

17. The method of manufacturing a semiconductor device according to claim 14,
wherein the step (d) includes the steps of:
(d1) introducing an impurity ion for forming the first diffusion layer for a source and drain and the first amorphous layer in the semiconductor substrate; and
(d2) introducing an impurity ion for reducing a melting point of the first amorphous layer, and
the step (f) includes the steps of:
(f1) introducing an impurity ion in the semiconductor substrate for forming the second diffusion layer for a source and drain and the second amorphous layer; and
(f2) introducing an impurity ion for reducing a melting point of the second amorphous layer.

18. The method of manufacturing a semiconductor device according to claim 14,
wherein the step (b) includes the steps of:
(b1) depositing a semiconductor film over the main surface of the semiconductor substrate including an upper surface of the gate insulator;
(b2) forming a first film having a function to increase a reflectance of the laser over the semiconductor film; and
(b3) pattering the semiconductor film and the first film into a shape of a gate electrode.

19. The method of manufacturing a semiconductor device according to claim 18,
wherein the first film includes a laminated film formed by depositing an insulator on a conductive film made of an aluminum material.

20. The method of manufacturing a semiconductor device according to claim 19,
wherein, after the step (f), an insulator with a desired thickness is deposited over the main surface of the semiconductor substrate, and then, the laser irradiation process in the step (g) is performed.

21. The method of manufacturing a semiconductor device according to claim 14,
wherein, after the step (f), a metal film with good heat conductivity is deposited over the main surface of the semiconductor substrate via an insulator, and then, the laser irradiation process in the step (g) is performed.

22. A semiconductor device having a field effect transistor, the field effect transistor comprising:
(a) a gate insulator formed over a semiconductor substrate;
(b) a gate electrode formed over the gate insulator;
(c) a sidewall insulator formed on a sidewall of the gate electrode;
(d) a diffusion layer for a source and drain formed over the semiconductor substrate so that a part of the diffusion layer is overlapped with the gate electrode when viewed from above; and
(e) a first region formed in a surface portion of the diffusion layer for a source and drain so as to apart from the gate electrode, the first region being melted and liquidized in a previous time.

23. The semiconductor device according to claim 22,
wherein the first region used to be an amorphous layer.

24. The semiconductor device according to claim 22,
wherein, in the semiconductor substrate, a diffusion layer having the same conductivity type as that of the diffusion layer for a source and drain is provided at a channel-side edge portion of the diffusion layer for a source and drain so that the diffusion layer is electrically connected to the diffusion layer for a source and drain and so that at least a part of the diffusion layer is overlapped with the gate electrode when viewed from above.

25. The semiconductor device according to claim 22,
wherein the diffusion layer for a source and drain contains an element for controlling a depth of the first region.

26. The semiconductor device according to claim 25,
wherein the element for controlling the depth of the first region is at least one of germanium and silicon.

27. The semiconductor device according to claim 22,
wherein the diffusion layer for a source and drain contains an impurity for reducing a melting point of the first region.

28. The semiconductor device according to claim 27,
wherein the element for reducing the melting point of the first region is at least one of indium, bismuth, lead, germanium, and antimony.

29. The semiconductor device according to claim 22,
wherein at least a part of the sidewall insulator is comprised of an insulator having a larger dielectric constant than that of a silicon oxide film.

30. The semiconductor device according to claim 29,
wherein the part of the sidewall insulator is comprised of an oxide film, a nitride film or a silicate film of silicon, aluminum, titanium, tantalum, zirconium, hafnium, palladium, or lanthanum.

31. The semiconductor device according to claim 22,
wherein the gate electrode includes a metal film.

32. The semiconductor device according to claim 31,
wherein the metal film of the gate electrode is made of aluminum, titanium, nickel, tantalum, molybdenum, tungsten, cobalt, or zirconium.

33. The semiconductor device according to claim 31,
wherein the gate electrode includes a semiconductor film containing an impurity at a position where the gate electrode and the gate insulator are contacted to each other.

34. The semiconductor device according to claim 22,
wherein the gate insulator includes an insulator having a relative dielectric constant larger than that of a silicon oxide film.

35. The semiconductor device according to claim 34,
wherein the gate insulator is comprised of an oxide film, a nitride film or a silicate film of silicon, aluminum, titanium, tantalum, zirconium, hafnium, palladium, or lanthanum.

36. The semiconductor device according to claim 22,
wherein the field effect transistor is designed to be operated in a state where a substrate potential of the field effect transistor is controlled to be a constant positive or negative potential.

37. A semiconductor device having a field effect transistor, the field effect transistor comprising:
(a) a gate insulator formed over a semiconductor substrate;
(b) a gate electrode formed on the gate insulator;
(c) a first sidewall insulator formed over a sidewall of the gate electrode;
(d) a second sidewall insulator formed on a sidewall of the first sidewall insulator;
(e) a first diffusion layer for a source and drain formed over the semiconductor substrate so that a part of the first diffusion layer is overlapped with the gate electrode when viewed from above;
(f) a first region formed in a surface portion of the first diffusion layer for a source and drain so as to apart from the gate electrode, the first region being melted and liquidized in a previous time;
(g) a second diffusion layer for a source and drain formed in the semiconductor substrate so as to have the same conductivity type as that of the first diffusion layer and to be electrically connected to the first diffusion layer; and
(h) a second region formed in a surface portion of the second diffusion layer for a source and drain so as to apart from the gate electrode, the second region being melted and liquidized in a previous time.
